(19) United States
(12) Patent Application Publication
(10) Pub. No.: US 2026/0180374 A1
(43) Pub. Date: Jun. 25, 2026

(54) DEVICE CAPABLE OF DETACHABLY COUPLED WITH ELECTRONIC DEVICE

(71) Applicant: SAMSUNG ELECTRONICS CO., LTD, Suwon-si (KR)

(72) Inventors: Kyoungwon KIM, Suwon-si (KR); Kiho CHO, Suwon-si (KR); Kiyun JO, Suwon-si (KR); Jongkui PARK, Suwon-si (KR); Kyuyoung KIM, Suwon-si (KR)

(73) Assignee: SAMSUNG ELECTRONICS CO., LTD, Suwon-si (KR)

(21) Appl. No.: 19/449,606

(22) Filed: Jan. 15, 2026

Related U.S. Application Data
(63) Continuation of application No. PCT/KR2025/022746, filed on Dec. 24, 2025.

(30) Foreign Application Priority Data
Dec. 24, 2024 (KR) 10-2024-0196132
Jan. 14, 2025 (KR) 10-2025-0005618
Jul. 7, 2025 (KR) 10-2025-0090994

(51) Int. Cl. H02J 50/70; H02J 50/10; H05K 5/03

(52) U.S. Cl. CPC H02J 50/70; H02J 50/10; H05K 5/03

(57) ABSTRACT

A device includes: a case configured to be detachably coupled to an electronic device including a camera and a planar induction coil, the case including a camera opening exposing a portion of the camera to an outside in a state in which the case is coupled to the electronic device; a magnetic structure disposed in or on the case and having a loop shape surrounding the planar induction coil; and a magnetic shielding member having a shape corresponding to the loop shape the magnetic structure, wherein the magnetic shielding member includes: a first portion interposed between the electronic device and the magnetic structure in the state in which the case is coupled to the electronic device and configured to cover a lower surface of the magnetic structure; and a second portion facing the camera opening and configured to cover an outer side surface of the magnetic structure.

### CROSS-REFERENCE TO RELATED APPLICATION(S)

This application is a continuation application of International Application No. PCT/KR2025/022746, filed on Dec. 24, 2025, which is based on and claims priority to Korean Patent Application No. 10-2025-0090994, filed on Jul. 7, 2025, Korean Patent Application No. 10-2025-0005618, filed on Jan. 14, 2025, and Korean Patent Application No. 10-2024-0196132, filed on Dec. 24, 2024, in the Korean Intellectual Property Office, the disclosures of which are incorporated by reference herein in their entireties.

### BACKGROUND

### 1. Field

The disclosure relates to a device that is detachably coupled with an electronic device, and more particularly, to a device that is detachably coupled with an electronic device having a wireless charging function.

### 2. Description of Related Art

Electronics devices, such as smartphones or tablets, may include rechargeable batteries.

The rechargeable batteries of the electronic devices may be charged using power supplied from an external power source. For example, the rechargeable batteries may be charged using a commercial power source or another external electronic device.

The rechargeable batteries of electronic devices may be charged by an external power source, either wired or wirelessly.

An electronic device capable of wireless charging may include an induction coil configured to receive power so as to charge a battery. The electronic device may use the induction coil to charge another external electronic device.

A wireless charging station (e.g., a wireless power transmission device) may include an induction coil for power transmission and may be connected to an external power source. Therefore, placing the electronic device on the wireless charging station may charge the battery of the electronic device.

### SUMMARY

According to an aspect of the disclosure, a device includes: a case configured to be detachably coupled to an electronic device including a camera and a planar induction coil, the case including: a first surface in contact with the electronic device in a state in which the case is coupled to the electronic device; a second surface opposite to the first surface; and a camera opening exposing at least a portion of the camera to an outside in a state in which the case is coupled to the electronic device; a magnetic structure disposed in or on the case and having a loop shape surrounding the planar induction coil of the electronic device in the state in which the case is coupled to the electronic device; and a magnetic shielding member having a shape corresponding to the loop shape of the magnetic structure, wherein the magnetic shielding member includes: a first portion interposed between the electronic device and the magnetic structure in the state in which the case is coupled to the electronic device and configured to cover a lower surface of the magnetic structure; and a second portion facing the camera opening and configured to cover an outer side surface of the magnetic structure.

The second portion of the magnetic shielding member may extend from an outer end of the first portion and is bent to cover the outer side surface of the magnetic structure, and the second portion of the magnetic shielding member may be configured to shield at least a portion of a magnetic field generated by the magnetic structure in a direction of the camera opening.

The magnetic shielding member may further include a third portion extending from an inner end of the first portion and bent to cover an inner side surface of the magnetic structure, and the third portion may be configured to shield at least a portion of the magnetic field generated by the magnetic structure in a direction of the planar induction coil of the electronic device.

A first height of the second portion of the magnetic shielding member may be equal to a second height of the third portion of the magnetic shielding member.

The second portion of the magnetic shielding member may completely cover the outer side surface of the magnetic structure, and the third portion of the magnetic shielding member may completely cover the inner side surface of the magnetic structure.

The magnetic shielding member may include: a first section including the first portion and the second portion; and a second section including the first portion without the second portion, and the first section may be closer to the camera opening than the second section.

The second section of the magnetic shielding member may include an opening from which a portion of the first portion of the magnetic structure is removed.

The case may further include another magnetic shielding member separated from the magnetic shielding member and disposed around the camera opening.

The magnetic structure may include a plurality of magnetic segments having an arc shape, and the first section may have a length corresponding to at least one magnetic segment among the plurality of magnetic segments.

The magnetic structure may be configured to couple the second surface of the case to an external electronic device including an external magnetic structure through attractive force between the magnetic structure and the external magnetic structure, and the plurality of magnetic segments of the magnetic structure may include a first magnetic segment group having a first magnetic pole arrangement configured to provide the attractive force to be coupled to the external magnetic structure of the external electronic device.

The plurality of magnetic segments may further include a second magnetic segment group that is closer to the camera opening than the first magnetic segment group and has a second magnetic pole arrangement different from the first magnetic pole arrangement.

The electronic device may include a Hall sensor, and the plurality of magnetic segments may further include a third magnetic segment having a third magnetic pole arrangement detected by the Hall sensor of the electronic device.

The first portion of the magnetic shielding member may be attached to the second surface of the case, and the magnetic shielding member is interposed between the case and the magnetic structure.

The magnetic structure may be attached to the first surface of the case, and the magnetic shielding member may cover the magnetic structure.

According to an aspect of the disclosure, an electronic device includes: a camera; a display; a battery overlapping at least a portion of the display; a cover including an opening through which at least a portion of the camera is exposed, the cover being configured to be coupled to an external case including a magnetic structure; a planar induction coil between the battery and an outer surface of the cover, the planar induction coil being configured to receive power for charging the battery; and a magnetic shielding member in or on the cover, surrounding at least a portion of an outer periphery of the planar induction coil, and having a loop shape, wherein the magnetic shielding member includes: a first portion between the cover and the magnetic structure and covering at least a portion of a surface of the magnetic structure based on the cover being coupled to the external case; and a second portion extending from an outer end of the first portion, bent in a direction opposite to the cover, and facing the camera.

The magnetic shielding member may include: a first section including the first portion and the second portion; and a second section including the first portion without the second portion, and the first section may be closer to the opening of the cover than the second section.

The electronic device may further include: a Hall sensor configured to recognize the magnetic structure; a memory storing instructions, and at least one processor configured to execute the instructions individually or collectively to, based on recognizing that the external case is coupled to the cover through the Hall sensor, control at least one of the camera or the display differently from a state in which the external case is not coupled to the cover.

According to an aspect of the disclosure, a device may include: a case configured to be detachably coupled with an electronic device including a camera and a planar induction coil, the case including: a first surface in contact with the electronic device; a second surface opposite to the first surface; and a camera opening exposing at least a portion of the camera to an outside in a state in which the case is coupled to the electronic device; a magnetic structure disposed in or on the case adjacent to the camera opening, having a loop shape, and surrounding the planar induction coil of the electronic device; and a magnetic shielding member having a shape corresponding to the magnetic structure, wherein the magnetic structure includes an inner magnet and an outer magnet disposed concentrically around the inner magnet, and the inner magnet and the outer magnet are disposed in a Halbach arrangement.

Magnetic poles of the inner magnet may be disposed vertically, magnetic poles of the outer magnet may be disposed horizontally, and a ratio of a width of the inner magnet to a width of the outer magnet may be 1:2.

Magnetic poles of the inner magnet may be disposed horizontally, magnetic poles of the outer magnet may be disposed vertically, and a ratio of a width of the inner magnet to a width of the outer magnet may be 2:1.

### BRIEF DESCRIPTION OF THE DRAWINGS

The above and/or other aspects, features, and advantages of certain embodiments of the disclosure will be more apparent from the following description taken in conjunction with the accompanying drawings, in which:

FIG. 1 is a block diagram illustrating an electronic device within a network environment according to one or more embodiments of the disclosure;

FIG. 2 is a perspective view illustrating a device according to one or more embodiments of the disclosure;

FIG. 3 is a rear perspective view illustrating a device according to one or more embodiments of the disclosure;

FIG. 4 is a view illustrating a device according to one or more embodiments of the disclosure;

FIG. 5 is a partial cross-sectional view illustrating the device of FIG. 4 taken along line A-A according to one or more embodiments of the disclosure;

FIG. 6 is a partial cross-sectional view illustrating the device of FIG. 4 taken along line A-A according to one or more embodiments of the disclosure;

FIG. 7 is a partial cross-sectional view illustrating the device of FIG. 4 taken along line B-B according to one or more embodiments of the disclosure;

FIG. 8 is a partial cross-sectional view illustrating a device according to one or more embodiments of the disclosure;

FIG. 9 is a partial view illustrating a device according to one or more embodiments of the disclosure;

FIG. 10 is a partial cross-sectional view illustrating the device of FIG. 9 taken along line C-C according to one or more embodiments of the disclosure;

FIG. 11 is a partial cross-sectional view illustrating a device according to one or more embodiments of the disclosure;

FIG. 12 is a partial view illustrating a device according to one or more embodiments of the disclosure;

FIG. 13 is a partial cross-sectional view illustrating the device of FIG. 12 taken along line D-D according to one or more embodiments of the disclosure;

FIG. 14 is a partial cross-sectional view illustrating the device of FIG. 12 taken along line E-E according to one or more embodiments of the disclosure;

FIG. 15 is a partial view illustrating a device according to one or more embodiments of the disclosure;

FIG. 16 is a partial cross-sectional view illustrating the device of FIG. 15 taken along line E-E according to one or more embodiments of the disclosure;

FIG. 17 is a perspective view illustrating a device according to one or more embodiments of the disclosure;

FIG. 18 is a partial cross-sectional view illustrating the device of FIG. 17 taken along line G-G according to one or more embodiments of the disclosure;

FIG. 19 is a view illustrating a device according to one or more embodiments of the disclosure;

FIG. 20 is a partial cross-sectional view illustrating the device of FIG. 19 taken along line H-H according to one or more embodiments of the disclosure;

FIG. 21 is a partial view illustrating a device according to one or more embodiments of the disclosure;

FIG. 22 is a partial cross-sectional view illustrating the device of FIG. 21 taken along line I-I according to one or more embodiments of the disclosure;

FIG. 23 is a partial view illustrating a device according to one or more embodiments of the disclosure;

FIG. 24 is a perspective view illustrating a state in which a device is coupled to an electronic device according to one or more embodiments of the disclosure;

FIG. 25 is a perspective view illustrating a state in which a device is separated from an electronic device according to one or more embodiments of the disclosure;

FIG. 26 is a perspective view illustrating an accessory cover coupled to an electronic device according to one or more embodiments of the disclosure;

FIG. 27 is a perspective view illustrating a state in which an accessory cover is separated from an electronic device according to one or more embodiments of the disclosure;

FIG. 28 is a bottom perspective view illustrating an accessory cover according to one or more embodiments of the disclosure;

FIG. 29 is a cross-sectional view illustrating a device to which an electronic device is coupled according to one or more embodiments of the disclosure;

FIG. 30 is a cross-sectional view illustrating a device to which an electronic device is coupled according to one or more embodiments of the disclosure;

FIG. 31 is a cross-sectional view illustrating a device to which an electronic device is coupled according to one or more embodiments of the disclosure;

FIG. 32 is a view illustrating a wireless charging system for charging an electronic device coupled with a device according to one or more embodiments of the disclosure;

FIG. 33 is a flowchart illustrating a method for an electronic device to recognize an accessory cover and a charging station according to one or more embodiments of the disclosure;

FIG. 34 is a flowchart illustrating a method for optimizing performance when an electronic device recognizes an accessory cover according to one or more embodiments of the disclosure;

FIG. 35 is a flowchart illustrating a method for optimizing performance when an electronic device recognizes an accessory cover and a charging station according to one or more embodiments of the disclosure;

FIG. 36 is a partial cross-sectional view illustrating a device according to one or more embodiments of the disclosure;

FIG. 37 is a partial cross-sectional view illustrating a device according to one or more embodiments of the disclosure; and

FIG. 38 is a partial cross-sectional view illustrating a device according to one or more embodiments of the disclosure.

### DETAILED DESCRIPTION

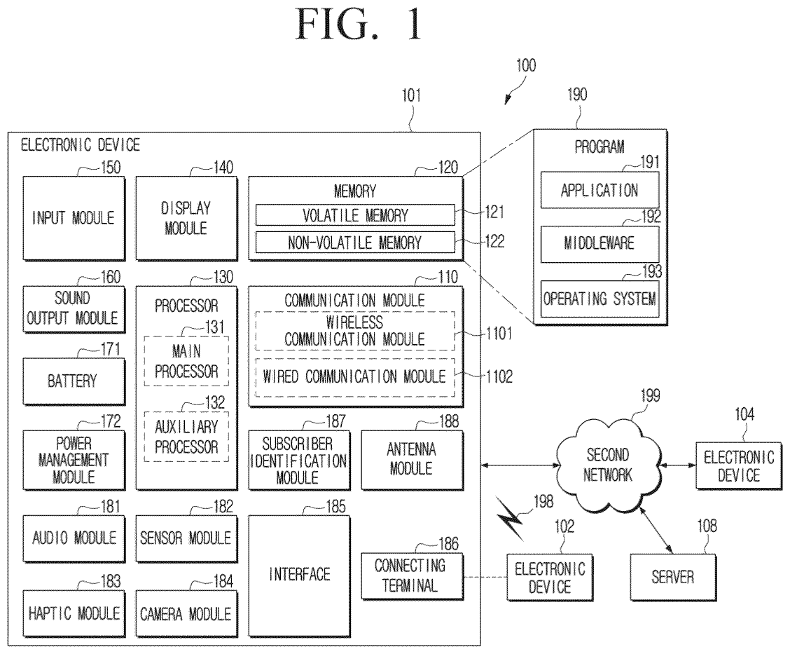

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include at least one processor 130, memory 120, an input module 170, a sound output module 160, a display module 140, an audio module 181, a sensor module 182, an interface 185, a connecting terminal 186, a haptic module 183, a camera module 184, a power management module 172, a battery 171, a communication module 110, a subscriber identification module (SIM) 187, or an antenna module 188. In some embodiments, at least one of the components (e.g., the connecting terminal 186) may be omitted from the electronic device 101, or one or more other components may be added in the electronic device 101. In some embodiments, some of the components (e.g., the sensor module 182, the camera module 184, or the antenna module 188) may be implemented as a single component (e.g., the display module 140).

The processor 130 may execute, for example, software (e.g., a program 190) to control at least one other component (e.g., a hardware or software component) of the electronic device 101 coupled with the processor 130, and may perform various data processing or computation. According to one embodiment, as at least part of the data processing or computation, the processor 130 may store a command or data received from another component (e.g., the sensor module 182 or the communication module 110) in volatile memory 121, process the command or the data stored in the volatile memory 121, and store resulting data in non-volatile memory 122. According to an embodiment, the processor 130 may include a main processor 131 (e.g., a central processing unit (CPU) or an application processor (AP)), or an auxiliary processor 132 (e.g., a graphics processing unit (GPU), a neural processing unit (NPU), an image signal processor (ISP), a sensor hub processor, or a communication processor (CP)) that is operable independently from, or in conjunction with, the main processor 131. For example, when the electronic device 101 includes the main processor 131 and the auxiliary processor 132, the auxiliary processor 132 may be adapted to consume less power than the main processor 131, or to be specific to a specified function. The auxiliary processor 132 may be implemented as separate from, or as part of the main processor 131.

The auxiliary processor 132 may control at least some of functions or states related to at least one component (e.g., the display module 140, the sensor module 182, or the communication module 110) among the components of the electronic device 101, instead of the main processor 131 while the main processor 131 is in an inactive (e.g., sleep) state, or together with the main processor 131 while the main processor 131 is in an active state (e.g., executing an application). According to an embodiment, the auxiliary processor 132 (e.g., an image signal processor or a communication processor) may be implemented as part of another component (e.g., the camera module 184 or the communication module 110) functionally related to the auxiliary processor 132. According to an embodiment, the auxiliary processor 132 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 120 may store various data used by at least one component (e.g., the processor 130 or the sensor module 182) of the electronic device 101. The various data may include, for example, software (e.g., the program 190) and input data or output data for a command related thereto. The memory 120 may include the volatile memory 121 or the non-volatile memory 122.

The program 190 may be stored in the memory 120 as software, and may include, for example, an operating system (OS) 193, middleware 192, or an application 191.

The input module 150 may receive a command or data to be used by another component (e.g., the processor 130) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 160 may output sound signals to the outside of the electronic device 101. The sound output module 160 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 140 may visually provide information to the outside (e.g., a user) of the electronic device 101. The display module 140 may include, for example, a display, a hologram device, or a projector and control circuitry to control a corresponding one of the display, hologram device, and projector. According to an embodiment, the display module 140 may include a touch sensor adapted to detect a touch, or a pressure sensor adapted to measure the intensity of force incurred by the touch.

The audio module 181 may convert a sound into an electrical signal and vice versa. According to an embodiment, the audio module 181 may obtain the sound via the input module 150, or output the sound via the sound output module 160 or a speaker of headphone of an external electronic device (e.g., an electronic device 102) directly (e.g., wiredly) or wirelessly coupled with the electronic device 101.

The sensor module 182 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 182 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 185 may support one or more specified protocols to be used for the electronic device 101 to be coupled with the external electronic device (e.g., the electronic device 102) directly (e.g., wiredly) or wirelessly. According to an embodiment, the interface 185 may include, for example, a high definition multimedia interface (HDMI), a universal serial bus (USB) interface, a secure digital (SD) card interface, or an audio interface.

A connecting terminal 186 may include a connector via which the electronic device 101 may be physically connected with the external electronic device (e.g., the electronic device 102). According to an embodiment, the connecting terminal 186 may include, for example, a HDMI connector, a USB connector, a SD card connector, or an audio connector (e.g., a headphone connector).

The haptic module 183 may convert an electrical signal into a mechanical stimulus (e.g., a vibration or a movement) or electrical stimulus which may be recognized by a user via his tactile sensation or kinesthetic sensation. According to an embodiment, the haptic module 183 may include, for example, a motor, a piezoelectric element, or an electric stimulator.

The camera module 184 may capture a still image or moving images. According to an embodiment, the camera module 184 may include one or more lenses, image sensors, image signal processors, or flashes.

The power management module 172 may manage power supplied to the electronic device 101. According to one embodiment, the power management module 172 may be implemented as at least part of, for example, a power management integrated circuit (PMIC).

The battery 171 may supply power to at least one component of the electronic device 101. According to an embodiment, the battery 171 may include, for example, a primary cell which is not rechargeable, a secondary cell which is rechargeable, or a fuel cell.

The communication module 110 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 110 may include one or more communication processors that are operable independently from the processor 130 (e.g., the application processor (AP)) and supports a direct (e.g., wired) communication or a wireless communication. According to an embodiment, the communication module 110 may include a wireless communication module 1101 (e.g., a cellular communication module, a short-range wireless communication module, or a global navigation satellite system (GNSS) communication module) or a wired communication module 1102 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1101 may identify and authenticate the electronic device 101 in a communication network, such as the first network 198 or the second network 199, using subscriber information (e.g., international mobile subscriber identity (IMSI)) stored in the subscriber identification module 187.

The wireless communication module 1101 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1101 may support a high-frequency band (e.g., the mmWave band) to achieve, e.g., a high data transmission rate. The wireless communication module 1101 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1101 may support various requirements specified in the electronic device 101, an external electronic device (e.g., the electronic device 104), or a network system (e.g., the second network 199). According to an embodiment, the wireless communication module 1101 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 188 may transmit or receive a signal or power to or from the outside (e.g., the external electronic device) of the electronic device 101. According to an embodiment, the antenna module 188 may include an antenna including a radiating element composed of a conductive material or a conductive pattern formed in or on a substrate (e.g., a printed circuit board (PCB)). According to an embodiment, the antenna module 188 may include a plurality of antennas (e.g., array antennas). In such a case, at least one antenna appropriate for a communication scheme used in the communication network, such as the first network 198 or the second network 199, may be selected, for example, by the communication module 110 (e.g., the wireless communication module 1101) from the plurality of antennas. The signal or the power may then be transmitted or received between the communication module 110 and the external electronic device via the selected at least one antenna. According to an embodiment, another component (e.g., a radio frequency integrated circuit (RFIC)) other than the radiating element may be additionally formed as part of the antenna module 188.

According to various embodiments, the antenna module 188 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. However, embodiments of disclosure are not limited to the electronic devices described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 190) including one or more instructions that are stored in a storage medium (e.g., internal memory or external memory) that is readable by a machine (e.g., the electronic device 101). For example, a processor (e.g., the processor 130) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

The disclosure relates to a device that can be detachably coupled with an electronic device.

For example, the electronic device 101 may include a camera module 184 and a battery 171. At least a portion of the camera module 184 may be exposed to the outside through a rear cover of the electronic device 101. The electronic device 101 may be configured to wirelessly charge the battery 171. The electronic device 101 may include an induction coil for wireless charging of the battery 171. The induction coil may be formed as a substantially flat surface, but is not limited thereto. The electronic device 101 may transmit power to another electronic device through the induction coil.

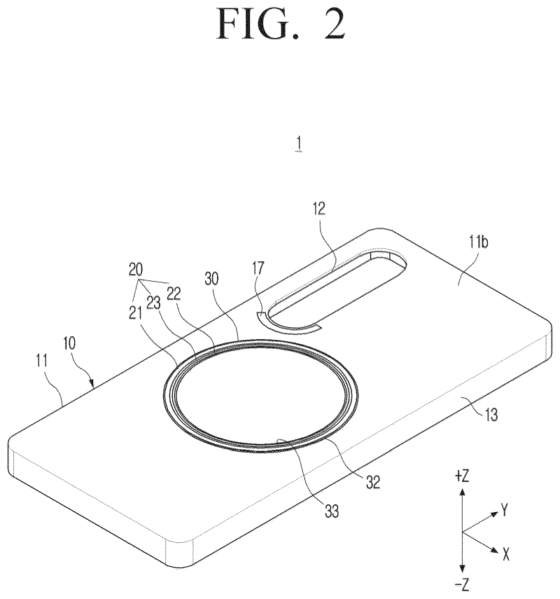

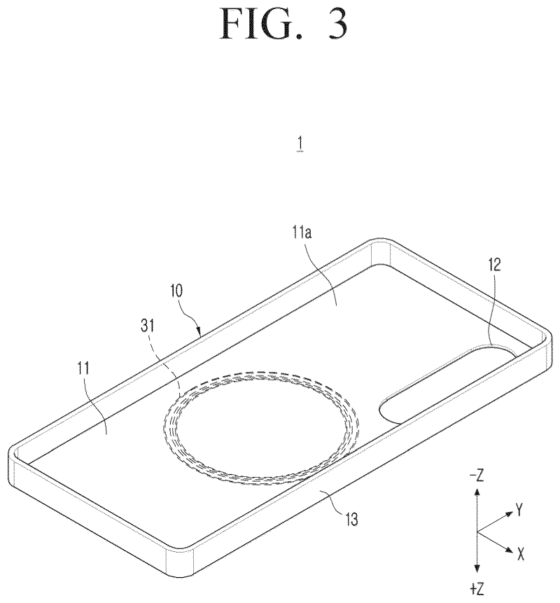

FIG. 2 is a perspective view illustrating a device according to one or more embodiments of the disclosure. FIG. 3 is a rear perspective view illustrating a device according to one or more embodiments of the disclosure.

Referring to FIGS. 2 and 3, a device 1 according to one or more embodiments of the disclosure may include a case 10, a magnetic structure 20, and a magnetic shielding member 30.

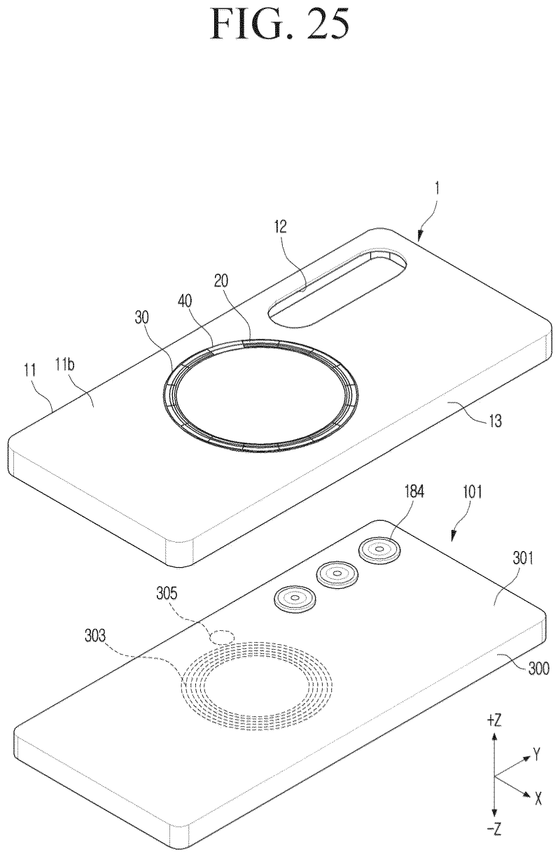

The case 10 may be configured to be detachably coupled to an electronic device 101 (see FIGS. 1 and 25). The case 10 may be configured to accommodate the electronic device 101 in a shape corresponding to the electronic device 101. For example, when the electronic device 101 has a rectangular flat plate shape, the case 10 may be formed in a basket shape with a substantially rectangular cross-section to accommodate the electronic device 101. However, the shape of the case 10 is not limited thereto. The case 10 may be formed in various shape (e.g., at least a portion of which is curved) corresponding to the shape of the electronic device 101.

According to an embodiment, the case 10 may include a bottom 11 and four side walls 13. The bottom 11 may be formed as a roughly rectangular flat plate, and the four side walls 13 may be formed to extend vertically from four sides of the bottom 11.

According to an embodiment, the case 10 may include a first surface 11a facing a first direction (e.g., in the −Z-axis direction) and contacting the electronic device 101, and a second surface 11b facing a second direction (e.g., in the +Z-axis direction) opposite to the first direction. For example, one surface of the bottom 11 from which the four side walls 13 of the case 10 extend may correspond to the first surface 11a, and the opposite surface of the one surface of the bottom 11 may correspond to the second surface 11b.

The case 10 may include a camera opening 12. The camera opening 12 may be configured so that at least a portion of the camera module 184 of the electronic device 101 is exposed to the outside when the electronic device 101 is coupled to the case 10. For example, the camera opening 12 may be formed in the bottom 11 of the case 10. The camera opening 12 may be provided to overlap with the camera module 184 (e.g., a plurality of cameras having a specific arrangement) equipped in the electronic device 101. In an embodiment, the camera opening 12 may be formed in an elongated oval shape in the Y-axis direction. However, the shape of the camera opening 12 is not limited thereto. The camera opening 12 may be provided in various shapes (e.g., an elongated rectangle in the X-axis direction, a substantially square shape) corresponding to the shape, size, position, and arrangement of the camera module 184 of the electronic device 101. As an example, the camera opening 12 may include a plurality of openings corresponding to respective lenses of the plurality of cameras included in the camera module 184.

According to an embodiment, a transparent plate (e.g., a transparent window) may be disposed in the camera opening 12. The transparent plate disposed in the camera opening 12 may cover the camera module 184 of the electronic device 101.

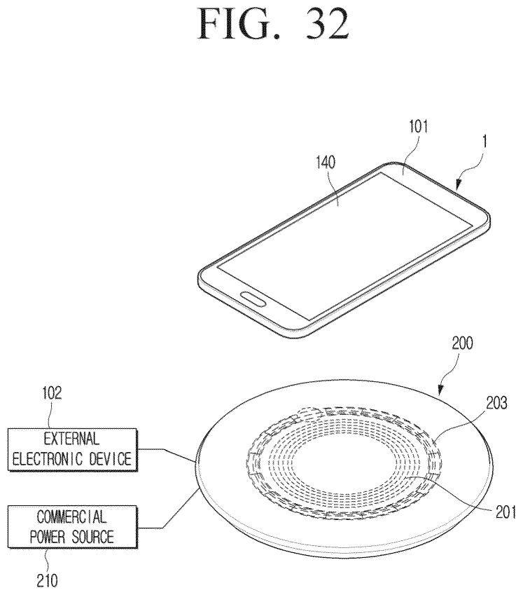

The magnetic structure 20 may be configured to provide an attractive force coupled with an external magnetic structure 203 of an external electronic device 200 (see FIG. 32). For example, the external electronic device may be a charging station 200 capable of charging the battery 171 (see FIG. 1) of the electronic device 101, and the external magnetic structure 203 may be a magnetic structure 203 disposed in the charging station 200 that may be magnetically coupled with the magnetic structure 20 of the device 1 according to one or more embodiments of the disclosure.

The magnetic structure 20 may be disposed in the case 10. The magnetic structure 20 may be disposed outside of the case 10. The magnetic structure 20 may be embedded in the case 10 (e.g., disposed between the first surface 11a and the second surface 11b). For example, the magnetic structure 20 may be disposed on the second surface 11b of the case 10. According to an embodiment, the magnetic structure 20 may be disposed adjacent to the camera opening 12 on the first surface 11a of the case 10.

The magnetic structure 20 may be configured to surround a planar induction coil 303 (see FIG. 25) of the electronic device 101 when the case 10 is coupled to the electronic device 101. For example, the magnetic structure 20 may be formed in a loop shape (or, ring shape, annular shape) that surrounds the planar induction coil 303. The magnetic structure 20 may be configured in an unsegmented loop shape. However, the shape of the magnetic structure 20 is not limited thereto. The magnetic structure 20 may be formed in various shapes (e.g., oval, square) corresponding to the shape of the planar induction coil 303 of the electronic device 101.

According to an embodiment, the magnetic structure 20 may include an outer magnet 21, a non-magnetic portion 23, and an inner magnet 22. The inner magnet 22, the non-magnetic portion 23, and the outer magnet 21 may be formed in a circular loop shape. The magnetic structure 20 may include a gap region in which some sections of the circular loop shape are empty. The inner magnet 22, the non-magnetic portion 23, and the outer magnet 21 may be formed to have a rectangular cross-section.

The inner magnet 22, the non-magnetic portion 23, and the outer magnet 21 may be arranged concentrically. The non-magnetic portion 23 may be disposed around the inner magnet 22, and the outer magnet 21 may be disposed around the non-magnetic portion 23. The outer circumferential surface of the inner magnet 22 may contact the inner circumferential surface of the non-magnetic portion 23. The outer circumferential surface of the non-magnetic portion 23 may contact the inner circumferential surface of the outer magnet 21.

The inner magnet 22 and the outer magnet 21 may be formed of permanent magnets. The non-magnetic portion 23 may be formed of a non-magnetic material.

According to an embodiment, the inner magnet 22 and the outer magnet 21 may be magnetized in a vertical direction. The magnetic force direction of the inner magnet 22 may be opposite to that of the outer magnet 21.

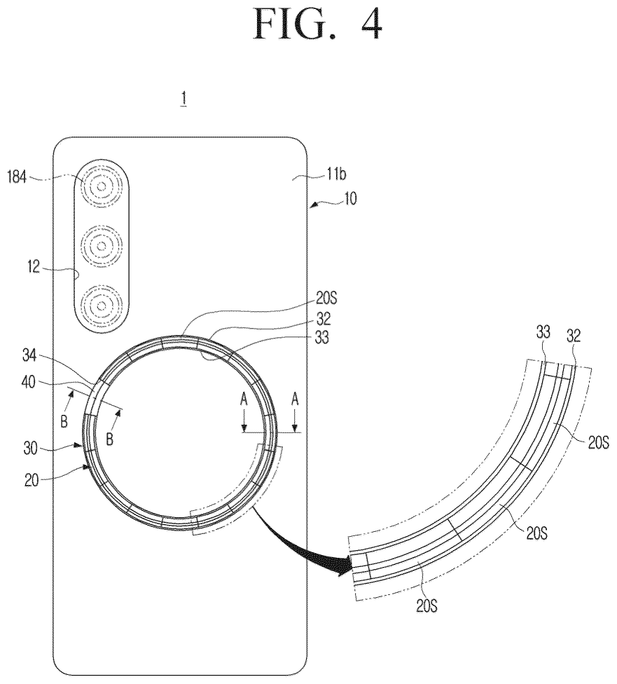

The magnetic shielding member 30 may be configured to reduce the magnetic force of the magnetic structure 20 in at least one direction. The magnetic field by the magnetic structure 20 may be partially reduced by the magnetic shielding member 30. The magnetic shielding member 30 may be formed in a shape corresponding to the magnetic structure 20. For example, the magnetic shielding member 30 may be formed in a circular loop shape. The magnetic shielding member 30 may include a gap region (e.g., an opening 34 in FIG. 4) in which a portion of the circular loop shape is empty. The gap region may be an empty space, or may be at least partially filled with a material other than the magnetic shielding member 30 (e.g., an insulator, a magnetic material, an adhesive). According to an embodiment, the magnetic shielding member 30 may be embedded in the case 10 (e.g., disposed between the first surface 11a and the second surface 11b).

According to an embodiment, the magnetic shielding member 30 may include a first portion 31 and a second portion 32.

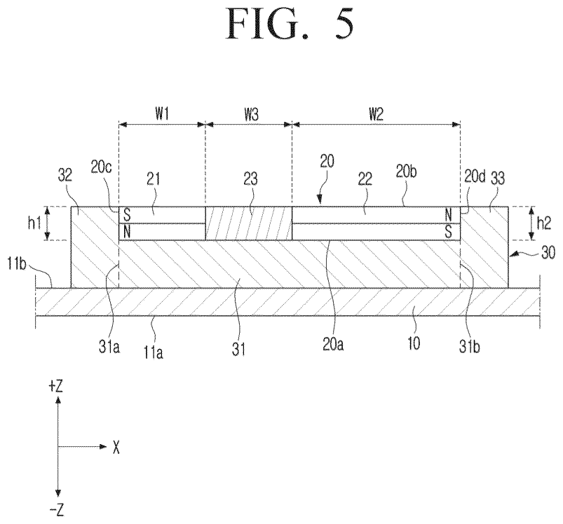

For example, the first portion 31 of the magnetic shielding member 30 may be disposed on the second surface 11b of the case 10. The first portion 31 may be configured to cover one surface 20a of the magnetic structure 20 (see FIG. 5). The first portion 31 and the magnetic structure 20 may be overlapped in the Z-axis direction. For example, the first portion 31 may be formed in a circular loop shape with a rectangular cross-section corresponding to the magnetic structure 20.

The first portion 31 of the magnetic shielding member 30 may be interposed between the second surface 11b of the case 10 and the magnetic structure 20. Accordingly, when the electronic device 101 is coupled to the case 10, the first portion 31 of the magnetic shielding member 30 may cover the one surface 20a (see FIG. 5) of the magnetic structure 20 adjacent to the electronic device 101.

For example, the second portion 32 of the magnetic shielding member 30 may be configured to cover the outer side surface 20c of the magnetic shielding member 30 (see FIG. 5). The second portion 32 may be provided to face the camera opening 12. The second portion 32 may be disposed to shield at least a portion of the magnetic force of the magnetic structure 20 acting on the camera module 184 of the electronic device 101 when the electronic device 101 is coupled to the case 10. For example, the second portion 32 may be configured to limit at least a portion of the magnetic field generated by the magnetic structure 20 in the direction of the camera opening 12.

For example, the second portion 32 may be formed to completely cover the outer side surface 20c of the magnetic structure 20. In other words, the second portion 32 may be formed to cover the entire circumference of the outer circumferential surface of the outer magnet 21 of the magnetic structure 20. For example, the second portion 32 may be formed to cover a portion of the outer side surface 20c of the magnetic structure 20. According to an embodiment, the second portion 32 may be formed to cover a portion of the outer side surface 20c of the magnetic structure 20 adjacent to the camera opening 12. Here, the extent of the outer side surface 20c of the magnetic structure 20 covered by the second portion 32 of the magnetic shielding member 30 may be defined by the influence of the magnetic field of the magnetic structure 20 acting on the camera module 184 of the electronic device 101 when the electronic device 101 is coupled to the case 10.

For example, the second portion 32 may extend from the outer end 31a of the first portion 31 (see FIG. 5) and may be bent to cover the outer side surface 20c of the magnetic structure 20.

According to an embodiment, the magnetic shielding member 30 may further include a third portion 33 formed to extend from the inner end 31b of the first portion 31 (see FIG. 5) and cover the inner side surface 20d of the magnetic structure 20 (see FIG. 5). The third portion 33 may be disposed to shield at least a portion of the magnetic force of the magnetic structure 20 acting on the planar induction coil 303 of the electronic device 101. For example, the third portion 33 may be formed to limit at least a portion of the magnetic field generated by the magnetic structure 20 in the direction of the planar induction coil 303 of the electronic device 101.

For example, the third portion 33 may be formed to completely cover the inner side surface 20d of the magnetic structure 20. In other words, the third portion 33 may be formed to cover the entire circumference of the inner circumferential surface of the inner magnet 22 of the magnetic structure 20. For example, the third portion 33 may be formed to cover a portion of the inner side surface 20d of the magnetic structure 20.

For example, the third portion 33 may extend from the inner end 31b of the first portion 31 (see FIG. 5) and may be bent to cover the inner side surface 20d of the magnetic structure 20. The height h2 of the third portion 33 may be formed to be the same as the height h1 of the second portion 32.

The magnetic shielding member 30 may be formed of a cold-rolled steel plate (e.g., steel plate cold commercial (SPCC)), galvanized iron (GI), a hot-rolled steel plate (e.g., steel plate hot rolled coil (SPHC)), or a nanocrystal series shieling agent (e.g., 1K-107B).

According to an embodiment, the case 10 may further include an additional magnetic shielding member 17. The additional magnetic shielding member 17 may be disposed to surround at least a portion of the camera opening 12. The additional magnetic shielding member 17 may be formed of the same material as the magnetic shielding member 30. The additional magnetic shielding member 17 may be configured to further reduce the magnetic force applied from the magnetic structure 20 toward the camera opening 12.

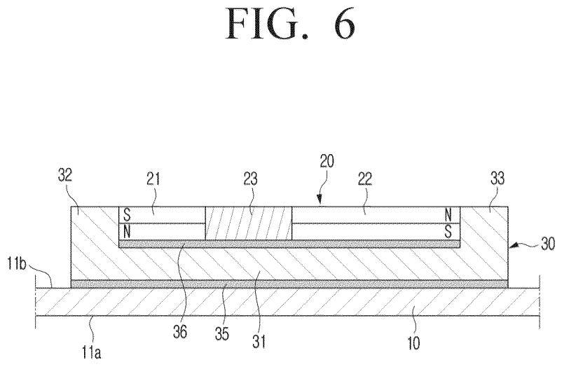

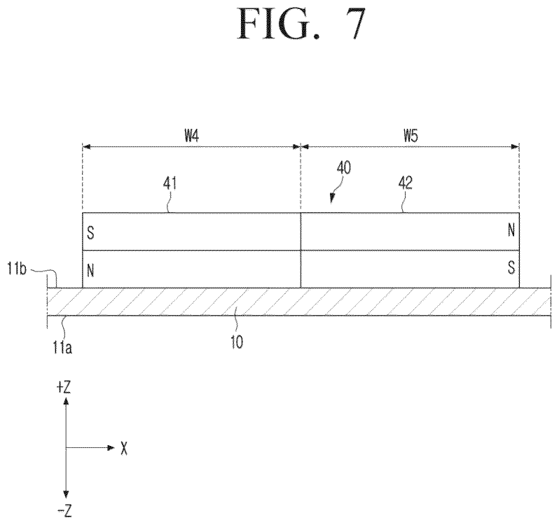

FIG. 4 is a view illustrating a device according to one or more embodiments of the disclosure. FIG. 5 is a partial cross-sectional view illustrating the device of FIG. 4 taken along line A-A according to one or more embodiments of the disclosure. FIG. 6 is a partial cross-sectional view illustrating the device of FIG. 4 taken along line A-A according to one or more embodiments of the disclosure. FIG. 7 is a partial cross-sectional view illustrating the device of FIG. 4 taken along line B-B according to one or more embodiments of the disclosure.

Referring to FIGS. 4, 5, 6 and 7, a device 1 according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. Because the case 10 is identical to the case 10 of the embodiment of FIGS. 2 and 3 described above, a duplicated description thereof is omitted.

The case 10 may include a camera opening 12. The camera opening 12 may be configured so that at least a portion of the camera module 184 of the electronic device 101 is exposed to the outside when the electronic device 101 is coupled to the case 10. For example, the camera opening 12 may be formed in the bottom 11 of the case 10. Accordingly, when the case 10 is coupled to the electronic device 101, the camera module 184 of the electronic device 101 may be positioned in the camera opening 12 of the case 10.

The magnetic shielding member 30 may be configured to limit the magnetic force of the magnetic structure 20 in at least one direction.

When the case 10 is coupled to the electronic device 101, the magnetic shielding member 30 may be configured to surround the planar induction coil 303 (see FIG. 25) of the electronic device 101 when viewed from the electronic device 101 toward the second surface 11b of the case 10. For example, the magnetic structure 20 may be formed in a loop shape that surrounds the planar induction coil 303 of the electronic device 101.

For example, the magnetic shielding member 30 may be formed in a circular loop shape. The cross-section of the magnetic shielding member 30 may be formed in a roughly U-shape with a flat bottom.

For example, the magnetic shielding member 30 may be disposed on the second surface 11b of the case 10. The magnetic shielding member 30 may be attached to the second surface 11b of the case 10 using an adhesive member 35. For example, a double-sided tape may be used as the adhesive member 35. The magnetic structure 20 may be disposed inside the magnetic shielding member 30.

According to an embodiment, the magnetic shielding member 30 may include a first portion 31, a second portion 32, and a third portion 33.

The first portion 31 may be disposed on the second surface 11b of the case 10. The first portion 31 may be configured to cover the lower surface 20a of the magnetic structure 20. The first portion 31 may be interposed between the second surface 11b of the case 10 and the magnetic structure 20. Accordingly, when the electronic device 101 is coupled to the case 10, the first portion 31 of the magnetic shielding member 30 may cover the lower surface 20a of the magnetic structure 20 adjacent to the electronic device 101.

The second portion 32 may be configured to cover the outer side surface 20c of the magnetic structure 20. The second portion 32 may extend from the outer end 31a of the first portion 31 and may be bent to cover the outer side surface 20c of the magnetic structure 20. The second portion 32 may be formed to completely cover the outer side surface 20c of the magnetic structure 20. At least a portion of the second portion 32 may be provided to face the camera opening 12. Accordingly, the second portion 32 may limit a portion of the magnetic field generated by the magnetic structure 20 in the direction of the camera opening 12.

The third portion 33 may be formed to cover the inner side surface 20d of the magnetic structure 20. The third portion 33 may extend from the inner end 31b of the first portion 31 and may be bent to cover the inner side surface 20d of the magnetic structure 20. The third portion 33 may be formed to completely cover the inner side surface 20d of the magnetic structure 20. Accordingly, the third portion 33 may limit at least a portion of the magnetic field generated by the magnetic structure 20 in the direction of the planar induction coil 303 of the electronic device 101.

The third portion 33 may be disposed concentrically with the second portion 32. The height h2 of the third portion 33 may be formed to be the same as the height h1 of the second portion 32.

According to an embodiment, the thickness of the second portion 32 and/or the third portion 33 may vary depending on the height. For example, the outer or inner side surface of the magnetic shielding member 30 may have an inclined shape.

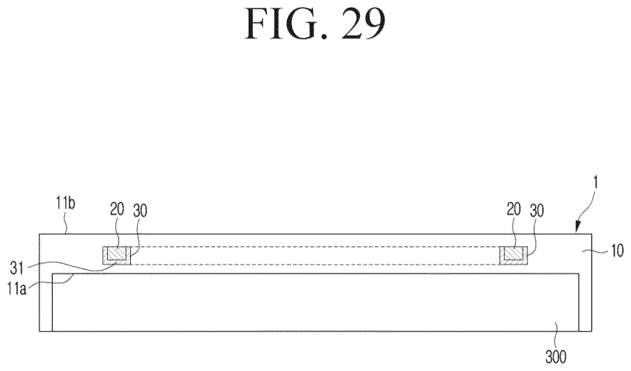

The magnetic structure 20 may be disposed in the magnetic shielding member 30. For example, at least a portion of the magnetic structure 20 may be accommodated in the magnetic shielding member 30. Accordingly, the first portion 31 of the magnetic shielding member 30 may cover the lower surface 20a of the magnetic structure 20, the second portion 32 may cover the outer side surface 20c of the magnetic structure 20, and the third portion 33 may cover the inner side surface 20d of the magnetic structure 20. The upper surface 20b of the magnetic structure 20 may not be covered by the magnetic shielding member 30. The upper surface 20b of the magnetic structure 20 may face the external magnetic structure 203 (see FIG. 29) of the external electronic device 200 (see FIG. 29).

According to an embodiment, the magnetic structure 20 may include a plurality of magnetic segments 20S. The plurality of magnetic segments 20S may be formed in an arc shape. The plurality of magnetic segments 20S may be disposed in a circular loop shape.

The plurality of magnetic segments 20S may be configured to provide an attractive force to be coupled with the external magnetic structure 203 (see FIG. 29) of the external electronic device 200 (see FIG. 29). The plurality of magnetic segments 20S may be configured to have the same magnetic pole arrangement.

The plurality of magnetic segments 20S may be formed in the same shape. Each of the plurality of magnetic segments 20S may include an inner magnet 22, a non-magnetic portion 23, and an outer magnet 21. The inner magnet 22, the non-magnetic portion 23, and the outer magnet 21 may each be formed, for example, in an arc shape with substantially the same radius of curvature. The inner magnet 22, the non-magnetic portion 23, and the outer magnet 21 may be formed to have a rectangular cross-section.

The inner magnet 22, the non-magnetic portion 23, and the outer magnet 21 may be disposed concentrically. The non-magnetic portion 23 may be disposed on the outer circumferential surface of the inner magnet 22, and the outer magnet 21 may be disposed on the outer circumferential surface of the non-magnetic portion 23.

The inner magnet 22 and the outer magnet 21 may be formed of permanent magnets. The non-magnetic portion 23 may be formed of a non-magnetic material.

According to an embodiment, the inner magnet 22 and the outer magnet 21 may be magnetized in a vertical direction. The magnetic force direction of the inner magnet 22 may be opposite to that of the outer magnet 21. For example, the outer magnet 21 may have the N pole positioned downward (e.g., in the −Z direction) and the S pole positioned upward (e.g., in the +Z-direction). The inner magnet 22 may have the S pole positioned downward (e.g., in the −Z direction) and the N pole positioned upward (e.g., in the +Z-direction).

According to an embodiment, the width W2 of the inner magnet 22 may be wider than the width W1 of the outer magnet 21. The width W1 of the outer magnet 21 may be the same as the width W3 of the non-magnetic portion 23. However, the width W2 of the inner magnet 22, the width W3 of the non-magnetic portion 23, and the width W1 of the outer magnet 21 may not be limited thereto. For example, the width W2 of the inner magnet 22 may be formed to be the same as or narrower than the width W1 of the outer magnet 21. The width W2 of the inner magnet 22 may be formed to be wider than the width W3 of the non-magnetic portion 23.

According to an embodiment, the width W1 of the outer magnet 21, the width W3 of the non-magnetic portion 23, and the width W2 of the inner magnet 22 of the magnetic structure 20 may be defined in various ratios as needed.

According to an embodiment, the magnetic segments 20S may be formed to have different widths and/or heights for the inner magnet 22, the non-magnetic portion 23, and/or the outer magnet 21. For example, the width W1 of the outer magnet 21 of the magnetic segment 20S adjacent to the camera opening 12 may be smaller than the width W1 of the outer magnets 21 of the other magnetic segments 20S.

Referring to FIG. 6, the magnetic shielding member 30 may be attached to the second surface 11b of the case 10 using an adhesive member 35. The magnetic structure 20, i.e., the plurality of magnetic segments 20S, may be attached to the first portion 31 of the magnetic shielding member 30 using an adhesive member 36. For example, double-sided tapes may be used as the adhesive members 35 and 36. For reference, in other drawings of this specification, for convenience of illustration, the adhesive member 35 that attaches the magnetic shielding member 30 to the case 10 and the adhesive member 36 that attaches the magnetic structure 20 to the magnetic shielding member 30 are not illustrated.

According to an embodiment, the magnetic structure 20 may include a sensing magnet 40. The sensing magnet 40 may be formed in a shape similar to the magnetic segments 20S. As illustrated in FIG. 4, the sensing magnet 40 may form a circular loop shape together with the plurality of magnetic segments 20S.

The sensing magnet 40 may be configured to be recognized by the Hall sensor 305 (see FIG. 25) of the electronic device 101. For example, the sensing magnet 40 may be configured as illustrated in FIG. 7.

The sensing magnet 40 may include an outer sensing magnet 41 and an inner sensing magnet 42. The inner sensing magnet 42 and the outer sensing magnet 41 may each be formed in an arc shape. The inner sensing magnet 42 and the outer sensing magnet 41 may be formed to have a rectangular cross-section.

The inner sensing magnet 42 and the outer sensing magnet 41 may be disposed concentrically. The outer sensing magnet 41 may be disposed on the outer circumferential surface of the inner sensing magnet 42.

The inner sensing magnet 42 and the outer sensing magnet 41 may be formed of permanent magnets.

According to an embodiment, the inner sensing magnet 42 and the outer sensing magnet 41 may be magnetized in the vertical direction. The magnetic force direction of the inner sensing magnet 42 may be opposite to that of the outer sensing magnet 41. For example, the outer sensing magnet 41 may have the N pole positioned downward (e.g., in the −Z direction) and the S pole positioned upward (e.g., in the +Z-direction). The inner sensing magnet 42 may have the S pole positioned downward (e.g., in the −Z direction) and the N pole positioned upward (e.g., in the +Z-direction).

According to an embodiment, the magnetic segments 20S that provide an attractive force to be coupled to the external magnetic structure 203 (see FIG. 29) of the external electronic device 200 (see FIG. 29) may be magnetized in the vertical direction, and the sensing magnet 40 that provides a magnetic field capable of detecting the device 1 through the Hall sensor 305 of the electronic device 101 may be magnetized in a horizontal direction. For example, the sensing magnet 40 may include a magnet that is magnetized horizontally with the N pole in an outward direction and the S pole in an inward direction.

According to an embodiment, a non-magnetic region or gap region may be included between the sensing magnet 40 and the magnetic segments 20S that provide the attractive force to be coupled with the external magnetic structure 203 (see FIG. 29).

For example, the width W5 of the inner sensing magnet 42 may be the same as the width W4 of the outer sensing magnet 41. For example, the width W4 of the outer sensing magnet 41 of the sensing magnet 40 may be wider than the width W1 of the outer magnets 21 of the other magnetic segments 20S.

According to an embodiment, the magnetic shielding member 30 may include an opening 34. A portion of the magnetic structure 20 may be exposed through the opening 34 of the magnetic shielding member 30. The opening 34 may be formed at a position corresponding to the sensing magnet 40 of the magnetic structure 20. For example, the magnetic shielding member 30 may be formed as a circular loop with a portion cut out. Accordingly, the sensing magnet 40 may be exposed through the opening 34 of the magnetic shielding member 30. Then, because the magnetic field of the sensing magnet 40 is not blocked by the magnetic shielding member 30, the Hall sensor 305 of the electronic device 101 may detect the sensing magnet 40.

According to an embodiment, the magnetic shielding member 30 may include a plurality of openings. Among two or more openings, a first opening may be positioned at a position overlapping with the sensing magnet 40, and a second opening may be positioned at a position overlapping with a component or circuit of the electronic device 101 (e.g., wiring connected to the planar induction coil 303 of the electronic device 101).

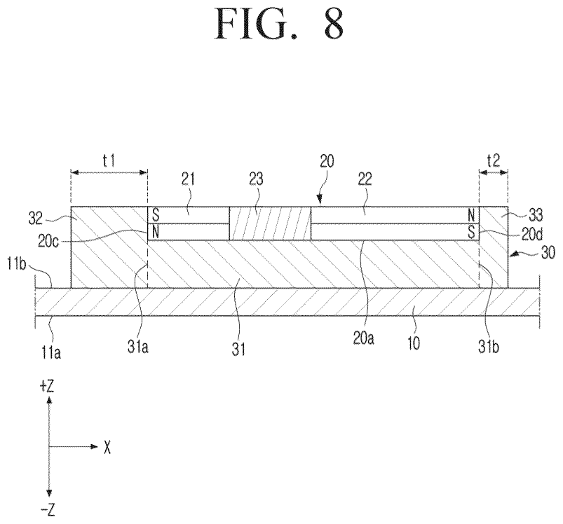

FIG. 8 is a partial cross-sectional view illustrating a device according to one or more embodiments of the disclosure.

According to an embodiment, as illustrated in FIG. 8, a second portion 32 and a third portion 33 of the magnetic shielding member 30 may be formed to have different thicknesses.

Referring to FIG. 8, the magnetic shielding member 30 may include a first portion 31 covering the lower surface 20a of the magnetic structure 20, the second portion 32 extending substantially vertically upward from the outer end 31a of the first portion 31 and covering the outer side surface 20c of the magnetic structure 20, and the third portion 33 extending substantially vertically upward from the inner end 31b of the first portion 31 and covering the inner side surface 20d of the magnetic structure 20.

For example, the thickness t1 of the second portion 32 may be formed to be thicker than the thickness t2 of the third portion 33. When the thickness t1 of the second portion 32 is thickened, the magnetic force of the magnetic structure 20 applied to the camera module 184 of the electronic device 101 mounted in the camera opening 12 of the case 10 may be further reduced. Therefore, malfunction of the camera module 184 of the electronic device 101 may be prevented, thereby improving the reliability of the electronic device 101.

According to an embodiment, the magnetic shielding member 30 may have a thickness of the second portion 32 that is thicker only in some sections (e.g., a region covering the magnetic segment 20S facing the camera opening 12) than in other sections.

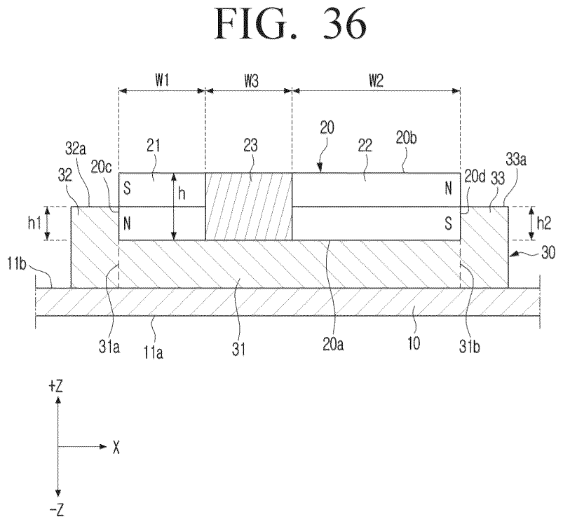

According to an embodiment, as illustrated in FIG. 36, the height (or thickness) h of the magnetic structure 20 may be formed to be greater than the height h1 of the second portion 32 and the height h2 of the third portion 33 of the magnetic shielding member 30.

FIG. 36 is a partial cross-sectional view illustrating a device according to one or more embodiments of the disclosure.

Referring to FIG. 36, the magnetic shielding member 30 may include a first portion 31 covering the lower surface 20a of the magnetic structure 20, a second portion 32 extending substantially vertically upward from the outer end 31a of the first portion 31 and covering the outer side surface 20c of the magnetic structure 20, and a third portion 33 extending substantially vertically upward from the inner end 31b of the first portion 31 and covering the inner side surface 20d of the magnetic structure 20.

For example, the height h1 of the second portion 32 and the height h2 of the third portion 33 may be formed to be lower than the height h of the magnetic structure 20. Accordingly, the upper surface 32a of the second portion 32 and the upper surface 33a of the third portion 33 may be positioned lower than the upper surface 20b of the magnetic structure 20 to form a step.

The height h1 of the second portion 32 may be the same as or different from the height h2 of the third portion 33.

By making the height h of the magnetic structure 20 higher than the heights h1 and h2 of the second portion 32 and the third portion 33 of the magnetic shielding member 30, the inductance of the planar induction coil 303 (see FIG. 25) of the electronic device 101 (see FIG. 25) may be increased.

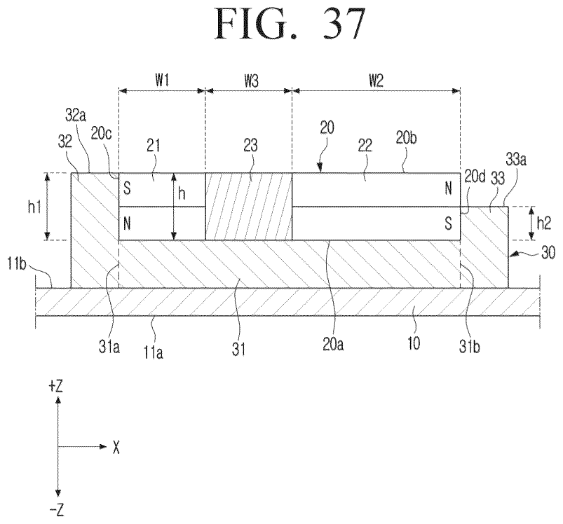

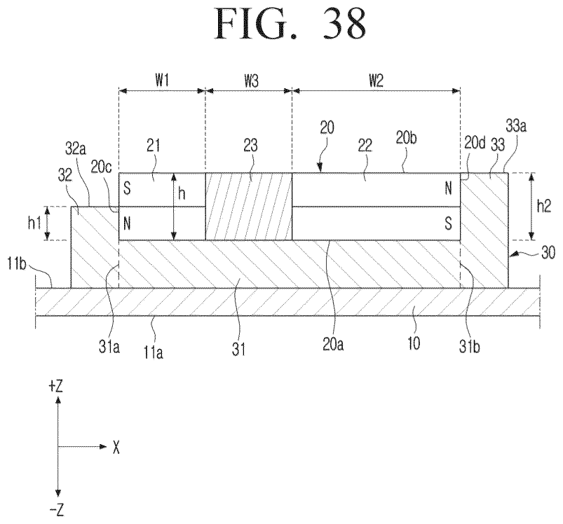

According to an embodiment, as illustrated in FIGS. 37 and 38, the height h1 of the second portion 32 and the height h2 of the third portion 33 of the magnetic shielding member 30 may be formed differently from each other.

FIG. 37 is a partial cross-sectional view illustrating a device according to one or more embodiments of the disclosure.

Referring to FIG. 37, the magnetic shielding member 30 may include a first portion 31 covering the lower surface 20a of the magnetic structure 20, a second portion 32 extending substantially vertically upward from the outer end 31a of the first portion 31 and covering the outer side surface 20c of the magnetic structure 20, and a third portion 33 extending substantially vertically upward from the inner end 31b of the first portion 31 and covering the inner side surface 20d of the magnetic structure 20.

For example, the height h1 of the second portion 32 may be formed higher than the height h2 of the third portion 33. The height h1 of the second portion 32 may be formed to be substantially the same as the height h of the magnetic structure 20. In other words, the upper surface 32a of the second portion 32 and the upper surface 20b of the magnetic structure 20 may form the same plane. The height h2 of the third portion 33 may be formed lower than the height h of the magnetic structure 20. In other words, the upper surface 33a of the third portion 33 may be positioned lower than the upper surface 20b of the magnetic structure 20 to form a step.

For example, the height h1 of the second portion 32 may be formed to be lower than the height h of the magnetic structure 20 and higher than the height h2 of the third portion 33.

For example, the second portion 32 may be formed to have a portion with the height h1 higher than the height h2 of the third portion 33, and the remaining portion with a height equal to or lower than the height h2 of the third portion 33.

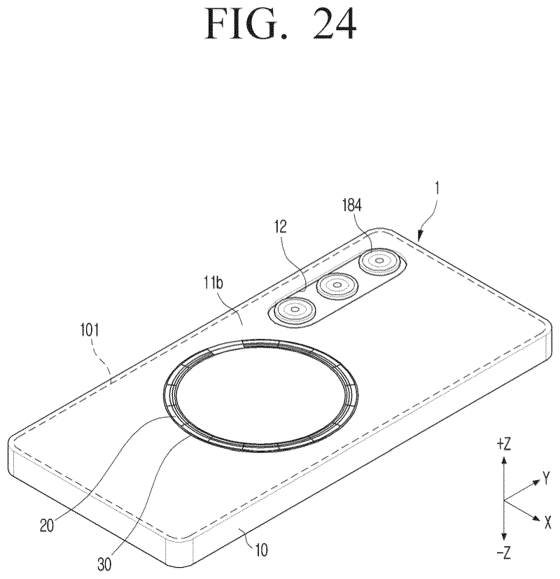

Increasing the height h1 of the second portion 32 may reduce the magnetic force of the magnetic structure 20 applied to the camera module 184 (see FIG. 24) of the electronic device 101 (see FIG. 24) mounted in the camera opening 12 of the case 10. Therefore, malfunction of the camera module 184 of the electronic device 101 may be prevented, thereby improving the reliability of the electronic device 101.

FIG. 38 is a partial cross-sectional view illustrating a device according to one or more embodiments of the disclosure.

Referring to FIG. 38, the magnetic shielding member 30 may include a first portion 31 covering the lower surface 20a of the magnetic structure 20, a second portion 32 extending substantially vertically upward from the outer end 31a of the first portion 31 and covering the outer side surface 20c of the magnetic structure 20, and a third portion 33 extending substantially vertically upward from the inner end 31b of the first portion 31 and covering the inner side surface 20d of the magnetic structure 20.

For example, the height h2 of the third portion 33 may be formed higher than the height h1 of the second portion 32. The height h2 of the third portion 33 may be formed to be substantially the same as the height h of the magnetic structure 20. In other words, the upper surface 33a of the third portion 33 and the upper surface 20b of the magnetic structure 20 may form the same plane. The height h1 of the second portion 32 may be formed lower than the height h of the magnetic structure 20. In other words, the upper surface 32a of the second portion 32 may be positioned lower than the upper surface 20b of the magnetic structure 20 to form a step.

For example, the height h2 of the third portion 33 may be formed to be lower than the height h of the magnetic structure 20 and higher than the height h1 of the second portion 32.

For example, the third portion 33 may be formed to have a portion with the height h2 higher than the height h1 of the second portion 32, and a remaining portion with a height equal to or lower than the height h1 of the second portion 32.

The height h2 of the third portion 33 may be defined to shield at least a portion of the magnetic force of the magnetic structure 20 acting on the planar induction coil 303 (see FIG. 25) of the electronic device 101 (see FIG. 25). For example, the height h2 of the third portion 33 may be defined to limit at least a portion of the magnetic field generated by the magnetic structure 20 in the direction of the planar induction coil 303 of the electronic device 101 to prevent the shielding material of the planar induction coil 303 of the electronic device 101 from being magnetized.

According to an embodiment, the second portion 32 and the third portion 33 of the magnetic shielding member 30 may be formed different materials. For example, the second portion 32 covering the outer side surface 20c of the magnetic structure 20 may be formed of a ferromagnetic material having high magnetic shielding performance, and the third portion 33 covering the inner side surface 20d of the magnetic structure 20 may be formed of a soft magnetic material having low magnetic shielding performance. In other words, the second portion 32 of the magnetic shielding member 30 may be formed of the same ferromagnetic material as the first portion 31, and the third portion 33 may be formed of a soft magnetic material different from the first portion 31.

For example, the first portion 31 and the second portion 32 of the magnetic shielding member 30 may be formed of a ferromagnetic material such as a cold-rolled steel plate, and the third portion 33 may be formed of a soft magnetic material such as iron, permalloy, sendust, or silicon steel plate.

By forming the second portion 32 of the magnetic shielding member 30 with a ferromagnetic material and the third portion 33 with a soft magnetic material, the magnetic field of the magnetic structure 20 acting on the camera module 184 of the electronic device 101 may be effectively shielded, and wireless charging performance through the inside of the magnetic shielding member 30 may be improved.

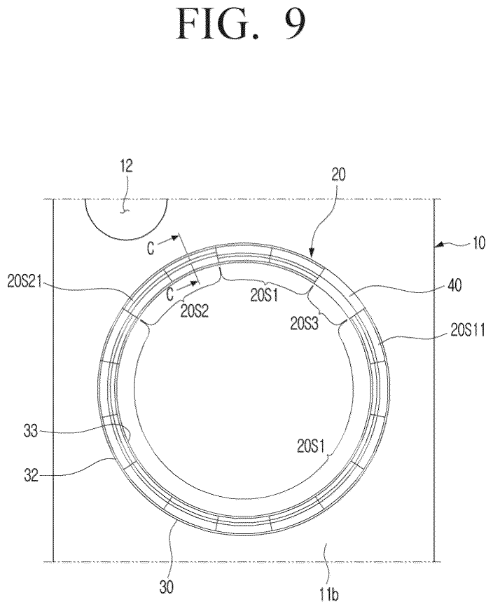

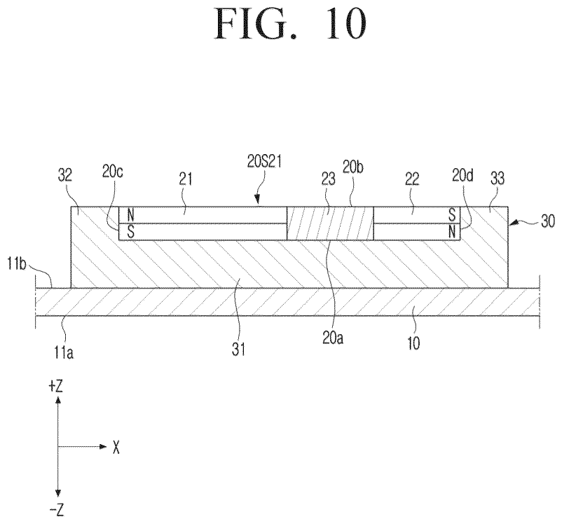

FIG. 9 is a partial view illustrating a device according to one or more embodiments of the disclosure. FIG. 10 is a partial cross-sectional view illustrating the device of FIG. 9 taken along line C-C according to one or more embodiments of the disclosure.

Referring to FIGS. 9 and 10, a device according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. Because the case 10 is identical to the case 10 of the embodiment of FIGS. 2 and 3 described above, a duplicated description thereof is omitted.

The magnetic shielding member 30 may be configured to shield at least a portion of the magnetic force of the magnetic structure 20 in at least one direction.

The magnetic shielding member 30 may be configured to surround the planar induction coil 303 (see FIG. 25) of the electronic device 101 when the case 10 is coupled to the electronic device 101. For example, the magnetic shielding member 30 may be formed in a loop shape capable of surrounding the planar induction coil 303 of the electronic device 101.

For example, the magnetic shielding member 30 may be formed in a circular loop shape. The cross-section of the magnetic shielding member 30 may be formed in a roughly U-shape with a flat bottom.

For example, the magnetic shielding member 30 may be disposed on the second surface 11b of the case 10. The magnetic shielding member 30 may be attached to the second surface 11b of the case 10 using an adhesive member. The magnetic structure 20 may be disposed inside the magnetic shielding member 30.

According to an embodiment, the magnetic shielding member 30 may include a first portion 31, a second portion 32, and a third portion 33. The structure of the magnetic shielding member 30 may be the same as the magnetic shielding member 30 illustrated in FIGS. 4, 5, and 6, and thus, a duplicated description thereof is omitted.

The magnetic structure 20 may be disposed in the magnetic shielding member 30. For example, at least a portion of the magnetic structure 20 may be accommodated in the magnetic shielding member 30. Accordingly, the first portion 31 of the magnetic shielding member 30 may cover the lower surface 20a of the magnetic structure 20, the second portion 32 may cover the outer side surface 20c of the magnetic structure 20, and the third portion 33 may cover the inner side surface 20d of the magnetic structure 20. The upper surface 20b of the magnetic structure 20 may be exposed to the outside without being covered by the magnetic shielding member 30.

According to an embodiment, the magnetic structure 20 may include a plurality of magnetic segments (e.g., the magnetic segments 20S of FIG. 4). The plurality of magnetic segments may be formed in an arc shape. The plurality of magnetic segments may be disposed in a circular loop shape.

According to an embodiment, the plurality of magnetic segments may be grouped into a first magnetic segment group 20S1, a second magnetic segment group 20S2, and a third magnetic segment group 20S3.

The first magnetic segment group 20S1 may be configured to provide an attractive force to be coupled to the external magnetic structure 203 of the external electronic device 200 (see FIG. 29). The first magnetic segment group 20S1 may be configured to have a first magnetic pole arrangement.

The first magnetic segment group 20S1 may include a plurality of first magnetic segments 20S11.

The first magnetic segments 20S11 of the first magnetic segment group 20S1 may include an inner magnet 22, a non-magnetic portion 23, and an outer magnet 21. The inner magnet 22, the non-magnetic portion 23, and the outer magnet 21 may each be formed in an arc shape. The inner magnet 22, the non-magnetic portion 23, and the outer magnet 21 may be formed to have a rectangular cross-section.

The inner magnet 22, the non-magnetic portion 23, and the outer magnet 21 may be disposed concentrically. The non-magnetic portion 23 may be disposed on the outer circumferential surface of the inner magnet 22, and the outer magnet 21 may be disposed on the outer circumferential surface of the non-magnetic portion 23.

The inner magnet 22 and the outer magnet 21 may be formed of permanent magnets. The non-magnetic portion 23 may be formed of a non-magnetic material.

For example, in the first magnetic pole arrangement, as illustrated in FIG. 5, the outer magnet 21 may have the N pole positioned downward (e.g., in the −Z direction) and the S pole positioned upward (e.g., in the +Z-direction), and the inner magnet 22 may have the S pole positioned downward (e.g., in the −Z direction) and the N pole positioned upward (e.g., in the +Z-direction).

The second magnetic segment group 20S2 may be closer to the camera opening 12 than the first magnetic segment group 20S1. The second magnetic segment group 20S2 may be configured to have a second magnetic pole arrangement different from the first magnetic pole arrangement of the first magnetic segment group 20S1.

The second magnetic segment group 20S2 may include at least one second magnetic segment 20S21.

The second magnetic segment 20S21 of the second magnetic segment group 20S2 may include an inner magnet 22, a non-magnetic portion 23, and an outer magnet 21. The inner magnet 22, the non-magnetic portion 23, and the outer magnet 21 may each be formed in an arc shape. The inner magnet 22, the non-magnetic portion 23, and the outer magnet 21 may be formed to have a rectangular cross-section.

The inner magnet 22, the non-magnetic portion 23, and the outer magnet 21 may be disposed concentrically. The non-magnetic portion 23 may be disposed on the outer circumferential surface of the inner magnet 22, and the outer magnet 21 may be disposed on the outer circumferential surface of the non-magnetic portion 23.

The inner magnet 22 and the outer magnet 21 may be formed of permanent magnets. The non-magnetic portion 23 may be formed of a non-magnetic material.

The second magnetic pole arrangement may be formed differently from the first magnetic pole arrangement (e.g., the arrangement of FIG. 5) of the first magnetic segment group 20S1. For example, in the second magnetic pole arrangement, as illustrated in FIG. 10, the outer magnet 21 may have the S pole positioned downward (e.g., in the −Z direction) and the N pole positioned upward (e.g., in the +Z-direction), and the inner magnet 22 may have the N pole positioned downward (e.g., in the −Z direction) and the S pole positioned upward (e.g., in the +Z-direction). By making the second magnetic pole arrangement of the second magnetic segment group 20S2 different from the first magnetic pole arrangement of the first magnetic segment group 20S1, the magnetic force acting on the camera module 184 of the electronic device 101 located in the camera opening 12 of the case 10 may be reduced.

The third magnetic segment group 20S3 may be configured to have a third magnetic pole arrangement. The third magnetic pole arrangement may be configured to be detected by the Hall sensor 305 of the electronic device 101. The third magnetic segment group 20S3 may be formed as a sensing magnet 40. For example, the third magnetic pole arrangement may be configured to have the same magnetic pole arrangement as the sensing magnet 40 illustrated in FIG. 7.

According to an embodiment, the size or shape of one of the first magnetic segment group 20S1, the second magnetic segment group 20S2, or the third magnetic segment group 20S3 may be distinct from the other segment groups. For example, the segment groups may have different lengths (arc lengths), thicknesses, or heights. The first magnetic segment group 20S1, the second magnetic segment group 20S2, or the third magnetic segment group 20S3 may include at least one magnetic segment.

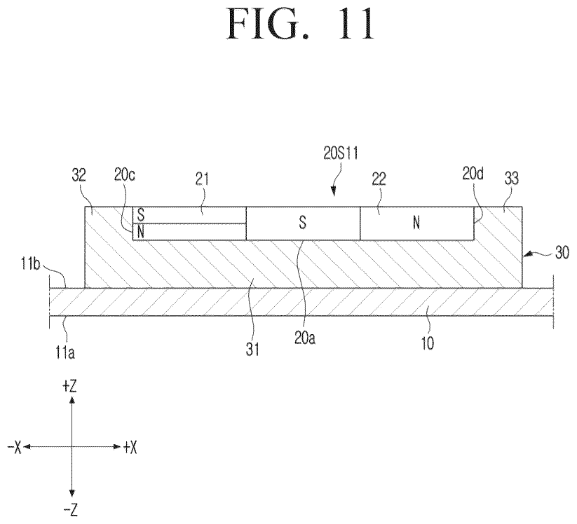

In the above, the first magnetic segments 20S11 of the first magnetic segment group 20S1 of the magnetic structure 20 disposed inside the magnetic shielding member 30 are formed with a structure including the inner magnet 22, the non-magnetic portion 23, and the outer magnet 21, but the structure of the first magnetic segment group 20S1 may not be limited thereto. As illustrated in FIG. 11, the first magnetic segments 20S11 of the first magnetic segment group 20S1 may be configured to have a Halbach arrangement (or Halbach array).

FIG. 11 is a partial cross-sectional view illustrating a device according to one or more embodiments of the disclosure.

Referring to FIG. 11, the first magnetic segment 20S11 of the first magnetic segment group 20S1 may be disposed inside the magnetic shielding member 30. For example, the lower surface 20a of the first magnetic segment 20S11 may be covered by the first portion 31 of the magnetic shielding member 30, the outer side surface 20c of the first magnetic segment 20S11 may be covered by the second portion 32 of the magnetic shielding member 30, and the inner side surface 20d of the first magnetic segment 20S11 may be covered by the third portion 33 of the magnetic shielding member 30.

The first magnetic segments 20S11 of the first magnetic segment group 20S1 may include an inner magnet 22 and an outer magnet 21. According to an embodiment, the inner magnet 22 and the outer magnet 21 may be disposed in a Halbach arrangement. For example, the inner magnet 22 and the outer magnet 21 may be formed such that the magnetic pole direction of the inner magnet 22 and the magnetic pole direction of the outer magnet 21 are perpendicular to each other.

For example, the inner magnet 22 may be magnetized horizontally, and the outer magnet 21 may be magnetized vertically. As an example, the inner magnet 22 may be formed so that the N pole is positioned inward (e.g., in the +X direction) and the S pole is positioned outward (e.g., in the −X direction). The outer magnet 21 may be formed so that the N pole is positioned downward (e.g., in the −Z direction) and the S pole is positioned upward (e.g., in the +Z direction).

According to an embodiment, one or more first magnetic segments 20S11 close to the camera opening 12 among the first magnetic segment group 20S1 may be arranged in the Halbach arrangement, and the remaining first magnetic segments 20S11 may be arranged as illustrated in FIG. 5.

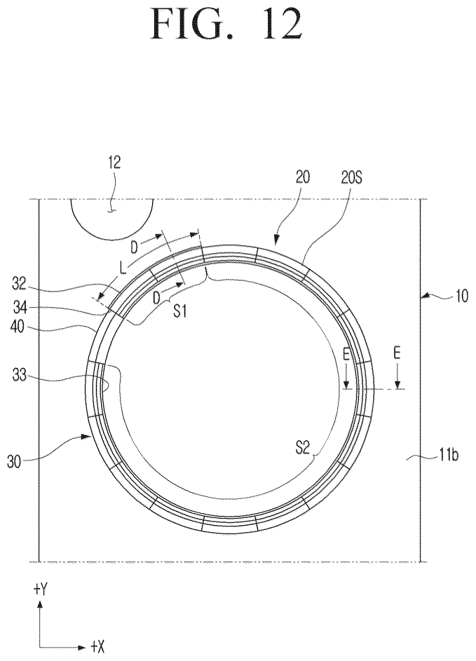

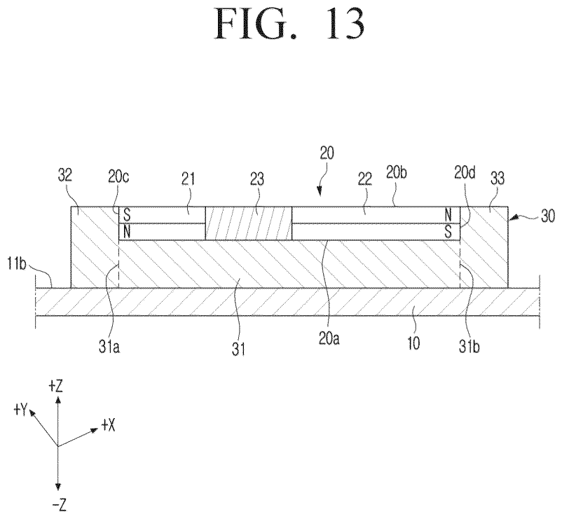

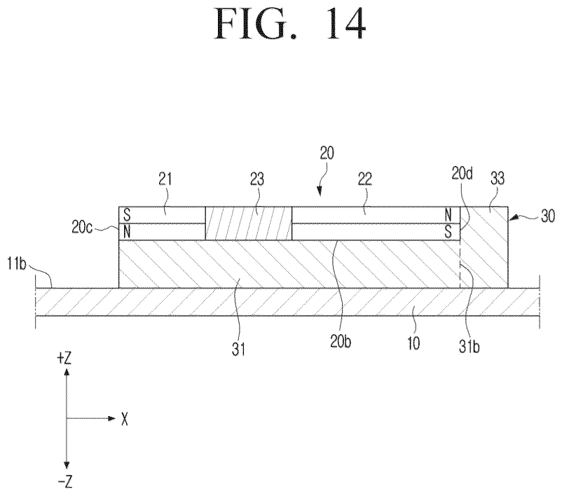

FIG. 12 is a partial view illustrating a device according to one or more embodiments of the disclosure. FIG. 13 is a partial cross-sectional view illustrating the device of FIG. 12 taken along line D-D according to one or more embodiments of the disclosure. FIG. 14 is a partial cross-sectional view illustrating the device of FIG. 12 taken along line E-E according to one or more embodiments of the disclosure.

Referring to FIGS. 12, 13, and 14, a device according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. Because the case 10 is identical to the case 10 of the embodiment of FIGS. 2 and 3 described above, a duplicated description thereof is omitted.

The magnetic shielding member 30 may be configured to shield at least a portion of the magnetic force of the magnetic structure 20 in at least one direction.

The magnetic shielding member 30 may be configured to surround the planar induction coil 303 (see FIG. 25) of the electronic device 101 when the case 10 is coupled to the electronic device 101. For example, the magnetic shielding member 30 may be formed in a loop shape capable of surrounding the planar induction coil 303 of the electronic device 101.

For example, the magnetic shielding member 30 may be formed in a circular loop shape.

The magnetic shielding member 30 may be disposed on the second surface 11b of the case 10. The magnetic structure 20 may be disposed in the magnetic shielding member 30.

According to an embodiment, the magnetic shielding member 30 may include a first portion 31, a second portion 32, and a third portion 33.

The first portion 31 may be disposed on the second surface 11b of the case 10. The first portion 31 may be formed to cover the lower surface 20a of the magnetic structure 20. The first portion 31 may be interposed between the second surface 11b of the case 10 and the magnetic structure 20. Accordingly, when the electronic device 101 is coupled to the case 10, the first portion 31 of the magnetic shielding member 30 may cover the lower surface 20a of the magnetic structure 20 adjacent to the electronic device 101.

The second portion 32 may be formed to cover the outer side surface 20c of the magnetic structure 20. The second portion 32 may extend from the outer end 31a of the first portion 31 and may be bent to cover the outer side surface 20c of the magnetic structure 20. The second portion 32 may be provided to cover the outer side surface 20c of the portion of the magnetic structure 20 that faces and is adjacent to the camera opening 12.

The remaining portion of the magnetic structure 20 not adjacent to the camera opening 12 of the case 10 may not be covered by the second portion 32 of the magnetic shielding member 30, as illustrated in FIG. 14.

The length L of the second portion 32 may be defined to shield at least a portion of the magnetic force of the magnetic structure 20 that affects the camera module 184 of the electronic device 101 coupled to the camera opening 12 of the case 10. Accordingly, the second portion 32 may limit at least a portion of the magnetic field generated by the magnetic structure 20 in the direction of the camera opening 12.

For example, the magnetic shielding member 30 may include a first section S1 and a second section S2. The first section S1 may include the first portion 31 in which the second portion 32 is formed. The second section S2 may include the first portion 31 in which the second portion 32 is not formed. In other words, the first section S1 of the magnetic shielding member 30 may include the first portion 31 and the second portion 32. The second section S2 may include the first portion 31 and not include the second portion 32.

The third portion 33 may be formed to cover the inner side surface 20d of the magnetic structure 20. The third portion 33 may extend from the inner end 31b of the first portion 31 and may be bent to cover the inner side surface 20d of the magnetic structure 20. The third portion 33 may be formed to completely cover the inner side surface 20d of the magnetic structure 20. According to an embodiment, the third portion 33 may be formed to cover at least a portion of the inner side surface 20d of the magnetic structure 20. Accordingly, the third portion 33 may limit at least a portion of the magnetic field generated by the magnetic structure 20 in the direction of the planar induction coil 303 of the electronic device 101.

The third portion 33 may be disposed concentrically with the second portion 32. The height of the third portion 33 (e.g., h2 in FIG. 5) may be formed to be the same as the height of the second portion 32 (e.g., h1 in FIG. 5).

For example, the first section S1 of the magnetic shielding member 30 may include the first portion 31, the second portion 32, and the third portion 33. The second section S2 may include the first portion 31 and the third portion 33, but may not include the second portion 32.

For example, the magnetic structure 20 may be disposed in the magnetic shielding member 30. The upper surface 20b of the magnetic structure 20 may be exposed to the outside without being covered by the magnetic shielding member 30.

According to an embodiment, the magnetic structure 20 may include a plurality of magnetic segments 20S. The plurality of magnetic segments 20S may be formed in an arc shape. The plurality of magnetic segments 20S may be disposed in a circular loop shape.

The plurality of magnetic segments 20S may be configured to provide an attractive force to be coupled with the external magnetic structure 203 of the external electronic device 200 (see FIG. 29). The plurality of magnetic segments 20S may be configured to have the same magnetic pole arrangement.

The magnetic structure 20 may include a sensing magnet 40. The sensing magnet 40 may be formed in a shape similar to the magnetic segments 20S. FIG. 12 illustrates an embodiment in which the position of the sensing magnet 40 differs from that of FIG. 9.

The magnetic structure 20 may be identical to the magnetic structure 20 according to the embodiment illustrated in FIGS. 4 to 7, and thus, a duplicated description thereof is omitted.

When the magnetic structure 20 includes the sensing magnet 40, the magnetic shielding member 30 may include an opening 34. One surface of the magnetic structure 20 may be exposed through the opening 34 of the magnetic shielding member 30. The opening 34 may be formed at a position corresponding to the sensing magnet 40 of the magnetic structure 20. For example, the magnetic shielding member 30 may be formed as a circular loop in which portions of the first portion 31 and the third portion 33 are cut off. Accordingly, the sensing magnet 40 may be exposed through the opening 34 of the magnetic shielding member 30. Then, because the magnetic field of the sensing magnet 40 is not blocked by the magnetic shielding member 30, the Hall sensor 305 of the electronic device 101 may detect the sensing magnet 40.

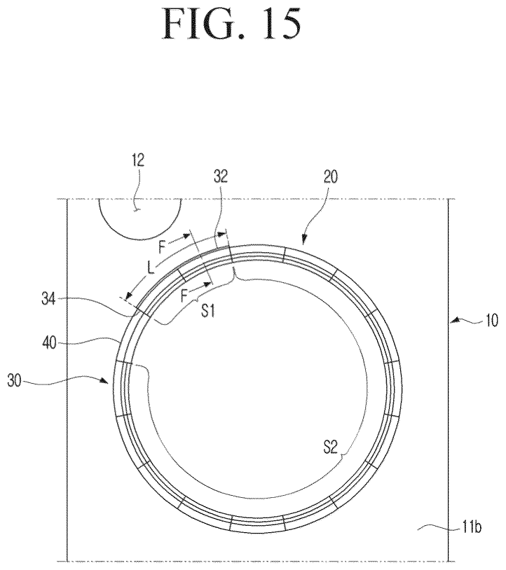

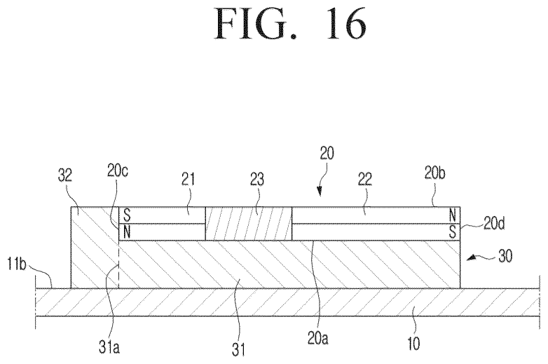

FIG. 15 is a partial view illustrating a device according to one or more embodiments of the disclosure. FIG. 16 is a partial cross-sectional view illustrating the device of FIG. 15 taken along line F-F according to one or more embodiments of the disclosure.

Referring to FIGS. 15 and 16, a device according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. Because the case 10 is identical to the case 10 of the embodiment of FIGS. 2 and 3 described above, a duplicated description thereof is omitted.

The magnetic shielding member 30 may be configured to shield at least a portion of the magnetic force of the magnetic structure 20 in at least one direction.

The magnetic shielding member 30 may be configured to surround the planar induction coil 303 (see FIG. 25) of the electronic device 101 when the case 10 is coupled to the electronic device 101. For example, the magnetic shielding member 30 may be formed in a circular loop capable of surrounding the planar induction coil 303 of the electronic device 101.

The magnetic shielding member 30 may be disposed on the second surface 11b of the case 10. The magnetic structure 20 may be disposed in the magnetic shielding member 30.

According to an embodiment, the magnetic shielding member 30 may include a first portion 31 and a second portion 32.

The first portion 31 may be disposed on the second surface 11b of the case 10. The first portion 31 may be formed to cover the lower surface 20a of the magnetic structure 20. The first portion 31 may be interposed between the second surface 11b of the case 10 and the magnetic structure 20. Accordingly, when the electronic device 101 is coupled to the case 10, the first portion 31 of the magnetic shielding member 30 may cover the lower surface 20a of the magnetic structure 20 adjacent to the electronic device 101.

The second portion 32 may be formed to cover the outer side surface 20c of the magnetic structure 20. The second portion 32 may extend from the outer end 31a of the first portion 31 and may be bent to cover the outer side surface 20c of the magnetic structure 20. The second portion 32 may be provided to cover the outer side surface 20c of the portion of the magnetic structure 20 that faces and is adjacent to the camera opening 12.

The outer side surface 20c of the remaining portion of the magnetic structure 20 that is not adjacent to the camera opening 12 of the case 10 may not be covered by the second portion 32.

The length L of the second portion 32 may be defined so as to shield at least a portion of the magnetic force of the magnetic structure 20 that affects the camera module 184 of the electronic device 101 coupled to the camera opening 12 of the case 10. Accordingly, the second portion 32 may limit at least a portion of the magnetic field generated by the magnetic structure 20 in the direction of the camera opening 12.

For example, the magnetic shielding member 30 may include a first section S1 and a second section S2. The first section S1 may include the first portion 31 in which the second portion 32 is formed. The second section S2 may include the first portion 31 in which the second portion 32 is not formed. In other words, the first section S1 of the magnetic shielding member 30 may include the first portion 31 and the second portion 32. The second section S2 may include the first portion 31 and not include the second portion 32.

The magnetic shielding member 30 illustrated in FIGS. 15 and 16 may not include a third portion 33 formed on the inner end of the first portion 31, unlike the magnetic shielding member 30 illustrated in FIGS. 12, 13, and 14.

For example, the magnetic structure 20 may be disposed in the magnetic shielding member 30. The upper surface 20b of the magnetic structure 20 may be exposed to the outside without being covered by the magnetic shielding member 30.

The magnetic structure 20 may be identical to the magnetic structure 20 according to the embodiment illustrated in FIGS. 4, 5, 6, and 7, and thus, a duplicated description thereof is omitted. FIG. 15 illustrates an embodiment in which the position of the sensing magnet 40 differs from that of FIG. 9.

When the magnetic structure 20 includes the sensing magnet 40, the magnetic shielding member 30 may include an opening 34. One surface of the magnetic structure 20 may be exposed through the opening 34 of the magnetic shielding member 30. The opening 34 may be formed at a position corresponding to the sensing magnet 40 of the magnetic structure 20. For example, the magnetic shielding member 30 may be formed as a circular loop in which a portion of the first portion 31 is cut off. Accordingly, the sensing magnet 40 may be exposed through the opening 34 of the magnetic shielding member 30. Then, because the magnetic field of the sensing magnet 40 is not blocked by the magnetic shielding member 30, the Hall sensor 305 of the electronic device 101 may detect the sensing magnet 40.

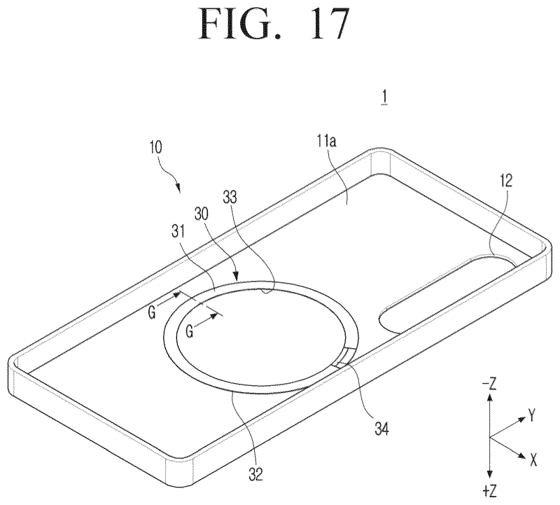

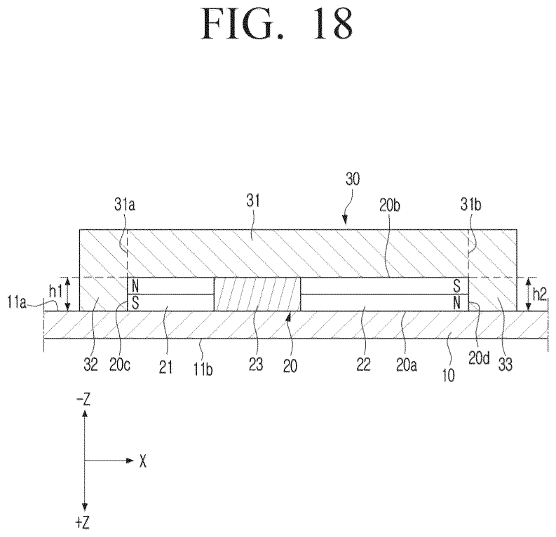

The above description describes the device 1 in which the magnetic structure 20 and the magnetic shielding member 30 are disposed on the outside of the case 10, i.e., on the second surface 11b of the case 10. However, the device 1 according to one or more embodiments of the disclosure may not be limited thereto. As illustrated in FIGS. 17 and 18, the magnetic structure 20 and the magnetic shielding member 30 may be disposed on a different surface of the case 10.

FIG. 17 is a perspective view illustrating a device according to one or more embodiments of the disclosure. FIG. 18 is a partial cross-sectional view illustrating the device of FIG. 17 taken along line G-G according to one or more embodiments of the disclosure.

Referring to FIGS. 17 and 18, a device 1 according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. When the case 10 is coupled to the electronic device 101, the camera module 184 of the electronic device 101 may be positioned in the camera opening 12 of the case 10. Because the case 10 is identical to the case 10 of the embodiment of FIGS. 2 and 3 described above, a duplicated description thereof is omitted.

The magnetic structure 20 may be configured to surround the planar induction coil 303 of the electronic device 101 when the case 10 is coupled to the electronic device 101. For example, the magnetic structure 20 may be formed in a circular loop capable of surrounding the planar induction coil 303 of the electronic device 101.

The magnetic structure 20 may be disposed on the first surface 11a of the case 10. The lower surface 20a of the magnetic structure 20 may be attached to the first surface 11a of the case 10 using an adhesive member (e.g., the adhesive member 35 in FIG. 6).

According to an embodiment, the magnetic structure 20 may include a plurality of magnetic segments 20S. The plurality of magnetic segments 20S may be formed in an arc shape. The plurality of magnetic segments 20S may be disposed in a circular loop shape.

The plurality of magnetic segments 20S may be configured to provide an attractive force that couples with the external magnetic structure 203 of the external electronic device 200 (see FIG. 29).

Each of the plurality of magnetic segments 20S may include an inner magnet 22, a non-magnetic portion 23, and an outer magnet 21. The non-magnetic portion 23 may be disposed on the outer circumferential surface of the inner magnet 22, and the outer magnet 21 may be disposed on the outer circumferential surface of the non-magnetic portion 23.

According to an embodiment, the inner magnet 22 and the outer magnet 21 may be magnetized in the vertical direction. The magnetic force direction of the inner magnet 22 may be opposite to that of the outer magnet 21. For example, the outer magnet 21 may be disposed so that the N pole is positioned upward (e.g., in the −Z direction) and the S pole is positioned downward (e.g., in the +Z-direction). The inner magnet 22 may be disposed so that the N pole is positioned downward (e.g., in the +Z-direction) and the S pole is positioned upward (e.g., in the −Z direction).

In addition, the plurality of magnetic segments 20S may be configured in the same manner as the plurality of magnetic segments 20S of the device according to the above-described embodiment, and thus, a duplicated description thereof is omitted.

The magnetic structure 20 may include a sensing magnet 40. The sensing magnet 40 may be formed in a shape similar to the magnetic segments 20S. FIG. 17 illustrates an embodiment in which the position of the sensing magnet 40 differs from that of FIG. 9. The sensing magnet 40 may be identical to the sensing magnet 40 of the device according to the above-described embodiment, and thus, a duplicated description thereof is omitted.

The magnetic shielding member 30 may be configured to shield at least a portion of the magnetic force of the magnetic structure 20 in at least one direction.

The magnetic shielding member 30 may be disposed on the upper surface 20b of the magnetic structure 20. The magnetic shielding member 30 may be disposed to cover the magnetic structure 20. The magnetic shielding member 30 may be attached to the upper surface 20b of the magnetic structure 20 using an adhesive member. Accordingly, the magnetic structure 20 may be disposed within the magnetic shielding member 30.

According to an embodiment, the magnetic shielding member 30 may include a first portion 31, a second portion 32, and a third portion 33.

The first portion 31 may be formed to cover the upper surface 20b of the magnetic structure 20. The magnetic structure 20 may be interposed between the first surface 11a of the case 10 and the first portion 31 of the magnetic shielding member 30. Accordingly, when the electronic device 101 is coupled to the case 10, the first portion 31 of the magnetic shielding member 30 may be adjacent to or in contact with the electronic device 101.

The second portion 32 may be formed to cover the outer side surface 20c of the magnetic structure 20. The second portion 32 may extend from the outer end 31a of the first portion 31 and may be bent to cover the outer side surface 20c of the magnetic structure 20. The second portion 32 may be formed to cover at least a portion of the outer side surface 20c of magnetic structure 20. The second portion 32 may be provided to face the camera opening 12. Therefore, the second portion 32 may limit at least a portion of the magnetic field generated by the magnetic structure 20 in the direction of the camera opening 12.

The third portion 33 may be formed to cover the inner side surface 20d of the magnetic structure 20. The third portion 33 may extend from the inner end 31b of the first portion 31 and may be bent to cover the inner side surface 20d of the magnetic structure 20. The third portion 33 may be formed to completely cover the inner side surface 20d of the magnetic structure 20. Accordingly, the third portion 33 may limit at least a portion of the magnetic field generated by the magnetic structure 20 in the direction of the planar induction coil 303 of the electronic device 101.

The third portion 33 may be disposed concentrically with the second portion 32. The height h2 of the third portion 33 may be formed to be the same as the height h1 of the second portion 32.

In addition, the magnetic shielding member 30 may be configured identically to the magnetic shielding member 30 of the device according to the above-described embodiment, and thus, a duplicated description thereof is omitted.

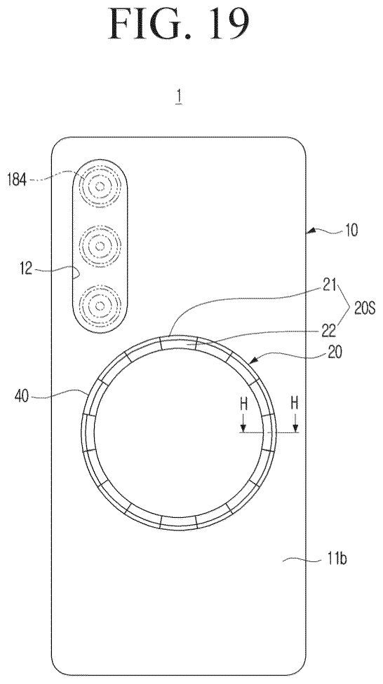

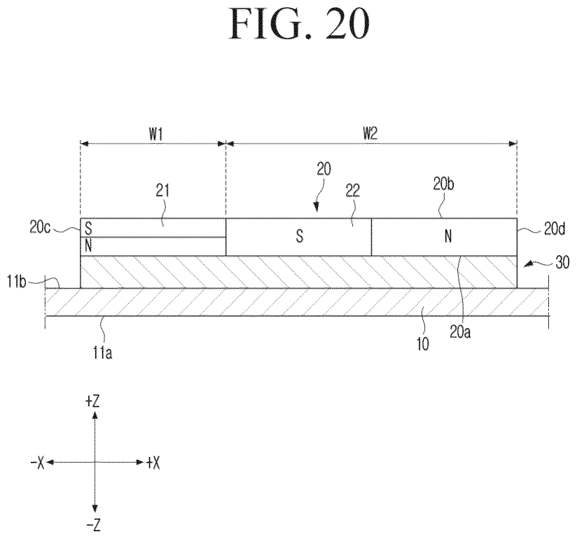

In the above description, the magnetic structure 20 is formed as a structure including the inner magnet 22, the non-magnetic portion 23, and the outer magnet 21, but the structure of the magnetic structure 20 may not be limited thereto. As illustrated in FIGS. 19 and 20, the magnetic structure 20 may be configured to have a Halbach arrangement.

FIG. 19 is a view illustrating a device according to one or more embodiments of the disclosure. FIG. 20 is a partial cross-sectional view illustrating the device of FIG. 19 taken along line H-H according to one or more embodiments of the disclosure.

Referring to FIGS. 19 and 20, a device according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. When the case 10 is coupled to the electronic device 101, the camera module 184 of the electronic device 101 may be positioned in the camera opening 12 of the case 10. Because the case 10 is identical to the case 10 of the embodiment of FIGS. 2 and 3 described above, a duplicated description thereof is omitted.

The magnetic shielding member 30 may be configured to shield at least a portion of the magnetic force of the magnetic structure 20 in at least one direction.

The magnetic shielding member 30 may be configured to surround the planar induction coil 303 of the electronic device 101 when the case 10 is coupled to the electronic device 101. For example, the magnetic shielding member 30 may be formed as a circular loop capable of surrounding the planar induction coil 303 of the electronic device 101.

The magnetic shielding member 30 may be disposed on the second surface 11b of the case 10. The magnetic structure 20 may be disposed in the magnetic shielding member 30.

According to an embodiment, the magnetic shielding member 30 may be formed to cover the lower surface 20a of the magnetic structure 20. The magnetic shielding member 30 may be interposed between the second surface 11b of the case 10 and the magnetic structure 20. Accordingly, when the electronic device 101 is coupled to the case 10, the magnetic shielding member 30 may cover the lower surface 20a of the magnetic structure 20 adjacent to the electronic device 101.

Unlike the magnetic shielding member 30 of the device according to the above-described embodiment, the magnetic shielding member 30 illustrated in FIGS. 19 and 20 may not include the second portion 32 and the third portion 33 covering the outer side surface 20c and the inner side surface 20d of the magnetic structure 20.

The magnetic structure 20 may be disposed on the magnetic shielding member 30. For example, the magnetic structure 20 may be fixed to the upper surface (e.g., in the +Z direction) of the magnetic shielding member 30. The upper surface 20b and both side surfaces 20c and 20d of the magnetic structure 20 may not be covered by the magnetic shielding member 30, thereby being exposed to the outside.

According to an embodiment, the magnetic structure 20 may include a plurality of magnetic segments 20S. The plurality of magnetic segments 20S may be formed in an arc shape. The plurality of magnetic segments 20S may be disposed in a circular loop shape.

The plurality of magnetic segments 20S may be configured to provide an attractive force to be coupled with the external magnetic structure 203 of the external electronic device 200.

Each of the plurality of magnetic segments 20S may be configured in a Halbach arrangement. Configuring the plurality of magnetic segments 20S in the Halbach arrangement may reduce the magnetic field emitted by the magnetic structure 20 in a horizontal direction.

According to an embodiment, the magnetic segments 20S may include an inner magnet 22 and an outer magnet 21. The inner magnet 22 and the outer magnet 21 may be arranged in the Halbach arrangement. For example, the inner magnet 22 and the outer magnet 21 may be configured such that the magnetic pole direction of the inner magnet 22 and the magnetic pole direction of the outer magnet 21 are perpendicular to each other. For example, the inner magnet 22 may be magnetized in a horizontal direction, and the outer magnet 21 may be magnetized in a vertical direction. As an example, the inner magnet 22 may be formed so that the N pole is positioned inward (e.g., in the +X direction) and the S pole is positioned outward (e.g., in the −X direction). The outer magnet 21 may be formed so that the N pole is positioned downward (e.g., in the −Z direction) and the S pole is positioned upward (e.g., in the +Z direction).

According to an embodiment, the magnetic segments 20S may be formed such that the width W1 of the outer magnet 21 and the width W2 of the inner magnet 22 are in a ratio of 1:2. By forming the outer magnet 21 and the inner magnet 22 of the magnetic segments 20S in this manner, the influence of the magnetic field applied to the camera module 184 of the electronic device 101 adjacent to the outer magnet 21 may be reduced.

The magnetic structure 20 may include a sensing magnet 40. The sensing magnet 40 may be formed in a shape similar to that of the magnetic segments 20S. Because the sensing magnet 40 is the same as the sensing magnet 40 of the device according to the above-described embodiment, a duplicated description thereof is omitted.

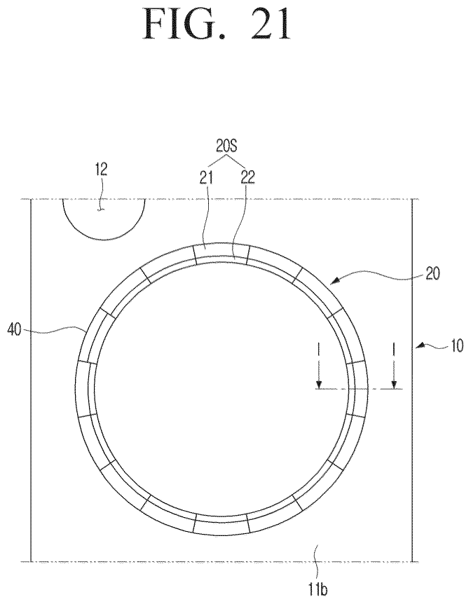

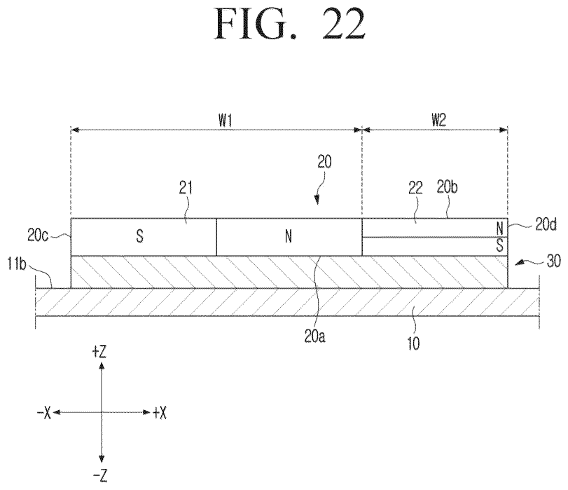

FIG. 21 is a partial view illustrating a device according to one or more embodiments of the disclosure. FIG. 22 is a partial cross-sectional view illustrating the device of FIG. 21 taken along line I-I according to one or more embodiments of the disclosure.

Referring to FIGS. 21 and 22, a device 1 according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. When the case 10 is coupled to the electronic device 101, the camera module 184 of the electronic device 101 may be positioned in the camera opening 12 of the case 10. Because the case 10 is identical to the case 10 of FIGS. 2 and 3 described above, a duplicated description thereof is omitted.

The magnetic shielding member 30 may be configured to shield at least a portion of the magnetic force of the magnetic structure 20 in at least one direction.

The magnetic shielding member 30 may be configured to surround the planar induction coil 303 of the electronic device 101 when the case 10 is coupled to the electronic device 101. For example, the magnetic shielding member 30 may be formed as a circular loop capable of surrounding the planar induction coil 303 of the electronic device 101.

The magnetic shielding member 30 may be disposed on the second surface 11b of the case 10. The magnetic structure 20 may be disposed on the upper surface (e.g., in the +Z direction) of the magnetic shielding member 30.

According to an embodiment, the magnetic shielding member 30 may be formed to cover the lower surface 20a of the magnetic structure 20. The magnetic shielding member 30 may be interposed between the second surface 11b of the case 10 and the magnetic structure 20. Accordingly, when the electronic device 101 is coupled to the case 10, the magnetic shielding member 30 may cover the lower surface 20a of the magnetic structure 20 adjacent to the electronic device 101.

Unlike the magnetic shielding member 30 of the device according to the above-described embodiment, the magnetic shielding member 30 illustrated in FIGS. 21 and 22 may not include the second portion 32 and the third portion 33 covering the outer side surface 20c and the inner side surface 20d of the magnetic structure 20.

The magnetic structure 20 may be disposed on the magnetic shielding member 30. For example, the magnetic structure 20 may be fixed to the upper surface (e.g., in the +Z direction) of the magnetic shielding member 30. The upper surface 20b and both side surfaces 20c and 20d of the magnetic structure 20 may be exposed to the outside without being covered by the magnetic shielding member 30.

According to an embodiment, the magnetic structure 20 may include a plurality of magnetic segments 20S. The plurality of magnetic segments 20S may be formed in an arc shape. The plurality of magnetic segments 20S may be disposed in a circular loop shape.

The plurality of magnetic segments 20S may be configured to provide an attractive force to be coupled with the external magnetic structure 203 of the external electronic device 200.

Each of the plurality of magnetic segments 20S may be configured in a Halbach arrangement. Configuring the plurality of magnetic segments 20S in the Halbach arrangement may reduce the magnetic field emitted by the magnetic structure 20 in a horizontal direction.

According to an embodiment, the magnetic segments 20S may include an inner magnet 22 and an outer magnet 21. The inner magnet 22 and the outer magnet 21 may be arranged in the Halbach arrangement. For example, the inner magnet 22 and the outer magnet 21 may be configured such that the magnetic pole direction of the inner magnet 22 and the magnetic pole direction of the outer magnet 21 are perpendicular to each other. For example, the inner magnet 22 may be magnetized in the vertical direction, and the outer magnet 21 may be magnetized in the horizontal direction. As an example, the inner magnet 22 may be formed so that the N pole is positioned upward (e.g., in the +Z direction) and the S pole is positioned downward (e.g., in the −Z direction). The outer magnet 21 may be formed so that the N pole is positioned inward (e.g., in the +X direction) and the S pole is positioned outward (e.g., in the −X direction).

According to an embodiment, the magnetic segments 20S may be formed such that the width W1 of the outer magnet 21 and the width W2 of the inner magnet 22 are in a ratio of 2:1. By forming the outer magnet 21 and the inner magnet 22 of the magnetic segments 20S in this manner, the influence of the magnetic field applied to the planar induction coil 303, for example, a wireless charging antenna and/or a magnetic secure transmission (MST) antenna, of the electronic device 101 located inside the magnetic structure 20 may be reduced.

The magnetic structure 20 may include a sensing magnet 40. The sensing magnet 40 may be formed in a shape similar to that of the magnetic segments 20S. FIG. 21 is an embodiment in which the position of the sensing magnet 40 is different from that of FIG. 9. Because the sensing magnet 40 is the same as the sensing magnet 40 of the device according to the above-described embodiment, a duplicated description thereof is omitted.

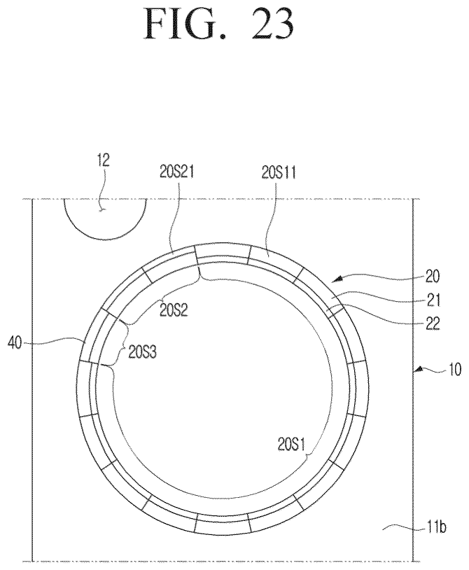

FIG. 23 is a partial view illustrating a device according to one or more embodiments of the disclosure.

Referring to FIG. 23, a device according to one or more embodiments of the disclosure may include a case 10, a magnetic structure 20, and a magnetic shielding member 30.

The case 10 may be configured to be detachably coupled to the electronic device 101. The case 10 may be configured to accommodate the electronic device 101 in a shape corresponding to the electronic device 101. The case 10 is identical to the case 10 of FIGS. 2 and 3 described above, and thus, a duplicated description thereof is omitted.

The magnetic shielding member 30 may be identical to the magnetic shielding member 30 of the device illustrated in FIGS. 21 and 22 described above, and thus, a duplicated description thereof is omitted.

The magnetic structure 20 may be disposed in the magnetic shielding member 30. For example, the magnetic structure 20 may be fixed to the upper surface (e.g., in the +Z direction) of the magnetic shielding member 30. The upper surface and both side surfaces of the magnetic structure 20 may be exposed to the outside without being covered by the magnetic shielding member 30 (see FIG. 22).

According to an embodiment, the magnetic structure 20 may include a plurality of magnetic segments. The plurality of magnetic segments may be formed in an arc shape. The plurality of magnetic segments may be disposed in a circular loop shape.

The plurality of magnetic segments may be configured to provide an attractive force to be coupled with the external magnetic structure 203 of the external electronic device 200.

According to an embodiment, the plurality of magnetic segments may be grouped into a first magnetic segment group 20S1, a second magnetic segment group 20S2, and a third magnetic segment group 20S3.

The first magnetic segment group 20S1 may be configured to provide an attractive force for coupling with the external magnetic structure 203 of the external electronic device 200. The first magnetic segment group 20S1 may be configured to have a first magnetic pole arrangement.

The first magnetic segment group 20S1 may include a plurality of first magnetic segments 20S11. In the embodiment illustrated in FIG. 23, the first magnetic segment group 20S1 may include thirteen first magnetic segments 20S11.

The plurality of first magnetic segments 20S11 of the first magnetic segment group 20S1 may be formed in a Halbach arrangement. According to an embodiment, the first magnetic segments 20S11 may include an inner magnet 22 and an outer magnet 21. The inner magnet 22 and the outer magnet 21 may be arranged in the Halbach arrangement. For example, the inner magnet 22 and the outer magnet 21 may be configured such that the magnetic pole direction of the inner magnet 22 and the magnetic pole direction of the outer magnet 21 are perpendicular to each other.

As an example, the inner magnet 22 and the outer magnet 21 of the first magnetic segments 20S11 may be configured as illustrated in FIG. 22. For example, the first magnetic segments 20S11 may be formed such that the width W1 of the outer magnet 21 and the width W2 of the inner magnet 22 are in a ratio of 2:1.

The second magnetic segment group 20S2 may be closer to the camera opening 12 than the first magnetic segment group 20S1. The second magnetic segment group 20S2 may be configured to have a second magnetic pole arrangement different from the first magnetic pole arrangement of the first magnetic segment group 20S1.

The second magnetic segment group 20S2 may include at least one second magnetic segment 20S21. In the embodiment illustrated in FIG. 23, the second magnetic segment group 20S2 may include two second magnetic segments 20S21.

The second magnetic segment 20S21 of the second magnetic segment group 20S2 may be formed in a Halbach arrangement. According to an embodiment, the second magnetic segments 20S21 may include an inner magnet 22 and an outer magnet 21. The inner magnet 22 and the outer magnet 21 may be arranged in the Halbach arrangement.

The second magnetic pole arrangement may be formed differently from the first magnetic pole arrangement of the first magnetic segments 20S11. For example, the inner magnet 22 and the outer magnet 21 may be formed such that the magnetic pole direction of the inner magnet 22 and the magnetic pole direction of the outer magnet 21 are perpendicular to each other. As an example, the inner magnet 22 and the outer magnet 21 of the second magnetic segment 20S21 may be formed as illustrated in FIG. 20. For example, the second magnetic segment 20S21 may be formed such that the width W1 of the outer magnet 21 and the width W2 of the inner magnet 22 are in a ratio of 1:2.

By making the second magnetic pole arrangement of the second magnetic segment group 20S2 different from the first magnetic pole arrangement of the first magnetic segment group 20S1, the influence of the magnetic field acting on the camera module 184 of the electronic device 101 located in the camera opening 12 of the case 10 may be reduced.

In the embodiment illustrated in FIG. 23, the second magnetic segment group 20S2 may include two second magnetic segments 20S21.

The third magnetic segment group 20S3 may be configured to have a third magnetic pole arrangement. The third magnetic segment group 20S3 may include one third magnetic segment. The third magnetic pole arrangement may be configured to be detected by the Hall sensor 305 of the electronic device 101. For example, the third magnetic pole arrangement may be configured to have the same magnetic pole arrangement as the sensing magnet 40 illustrated in FIG. 7. In other words, the third magnetic segment group 20S3 may be configured as the sensing magnet 40 of the device 1 according to the embodiment described above.

According to an embodiment, the first magnetic segment group 20S1, the second magnetic segment group 20S2, and the third magnetic segment group 20S3 of the magnetic structure 20 may all provide attractive forces that can adhere to the external magnetic structure 203, but the second magnetic segment group 20S2 and the third magnetic segment group 20S3 may provide less attractive forces than the first magnetic segment group 20S1.

FIG. 24 is a perspective view illustrating a state in which a device is coupled to an electronic device according to one or more embodiments of the disclosure. FIG. 25 is a perspective view illustrating a state in which a device is separated from an electronic device according to one or more embodiments of the disclosure.

Referring to FIGS. 24 and 25, a device 1 according to one or more embodiments of the disclosure may be coupled to an electronic device 101.

The device 1 according to one or more embodiments of the disclosure may include a case 10, a magnetic structure 20, and a magnetic shielding member 30. The case 10, the magnetic structure 20, and the magnetic shielding member 30 may be identical to those of the embodiment described above, and thus, duplicated descriptions thereof are omitted. According to an embodiment, the device 1 according to one or more embodiments of the disclosure may be configured as an accessory cover.

The magnetic shielding member 30 and the magnetic structure 20 may be disposed on the outer surface, i.e., the second surface 11b, of the case 10. According to an embodiment, the magnetic shielding member 30 and the magnetic structure 20 may be disposed on the other surface, i.e., the first surface 11a, of the case 10.

The electronic device 101 may be coupled to the case 10. According to an embodiment, the electronic device 101 may be configured as a smartphone. For example, the electronic device 101 may include a housing 300, a rear cover 301, a camera module 184, a planar induction coil 303, and a Hall sensor 305.

For example, the housing 71 may be configured to support a display module 140 (see FIG. 1). The display module 140 may be disposed on the front side (e.g., in the −Z direction) of the housing 300. The housing 300 may include a battery 171, a printed circuit board, and a charging device inside the housing 300.

The rear cover 301 may be configured to cover the rear side (e.g., in the +Z direction) of the housing 300. At least a portion of the camera module 184 may be exposed through a region of the rear cover 301. The rear cover 301 may be formed separately from the housing 300. Alternatively, the rear cover 301 may be formed integrally with the housing 300.

The planar induction coil 303 may be disposed between the rear cover 301 and the battery 171. The planar induction coil 303 may be configured to function as a wireless charging antenna and/or an MST antenna.

The Hall sensor 305 may be configured to recognize the sensing magnet 40 of the device 1 according to one or more embodiments of the disclosure. A processor 130 of the electronic device 101 (see FIG. 1) may include a threshold value set to recognize the device 1. When a signal transmitted from the Hall sensor 305 exceeds the threshold value, the processor 130 may recognize that the device 1 according to one or more embodiments of the disclosure including the magnetic structure 20 and the magnetic shielding member 30 is mounted to the electronic device 101.

According to an embodiment, when the electronic device 101 is a foldable device, the Hall sensor 305 may be used by the processor 130 to recognize that the electronic device 101 is in a folded state or an unfolded state.

The Hall sensor 305 may be disposed in the housing 300 under the rear cover 301. The Hall sensor 305 may be disposed to be adjacent to the sensing magnet 40 of the magnetic structure 20 when the electronic device 101 is coupled to the device 1 according to one or more embodiments of the disclosure.

As illustrated in FIG. 24, when the case 10 is coupled to the electronic device 101, the rear cover 301 of the electronic device 101 may be in contact with or adjacent to the first surface 11a of the case 10. At least a portion of the camera module 184 provided on the rear cover 301 of the electronic device 101 may be exposed to the outside through the camera opening 12 of the case 10. The planar induction coil 303 of the electronic device 101 may be located inside the magnetic shielding member 30 of the case 10, i.e., below the inner circle formed by the inner circumferential surface of the magnetic shielding member 30, when viewed from above (e.g., in the +Z direction). The Hall sensor 305 of the electronic device 101 may be located below the sensing magnet 40 so as to be adjacent to the sensing magnet 40 of the magnetic structure 20 of the case 10. The Hall sensor 305 may be disposed so as not to be adjacent to other magnetic segments of the magnetic structure 20 (e.g., S1 and S2 in FIG. 12) other than the sensing magnet 40 of the case 10.

The position of the sensing magnet 40 of the device 1 according to one or more embodiments of the disclosure may correspond to the position of the Hall sensor 305 of the electronic device 101.

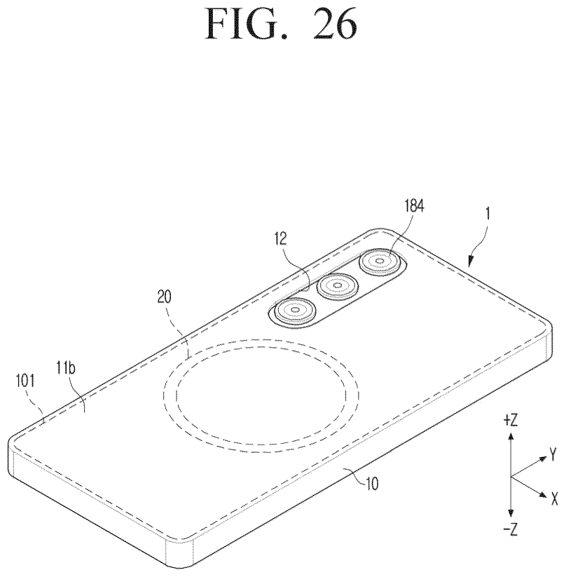

In the above, the magnetic structure 20 and the magnetic shielding member 30 are disposed in the device 1 according to one or more embodiments of the disclosure, such as an accessory cover. However, the device 1 according to one or more embodiments of the disclosure may not be limited thereto. According to an embodiment, as illustrated in FIGS. 26, 27, and 28, the magnetic shielding member 30 may be disposed in the electronic device 101, and the magnetic structure 20 may be disposed in the accessory cover.

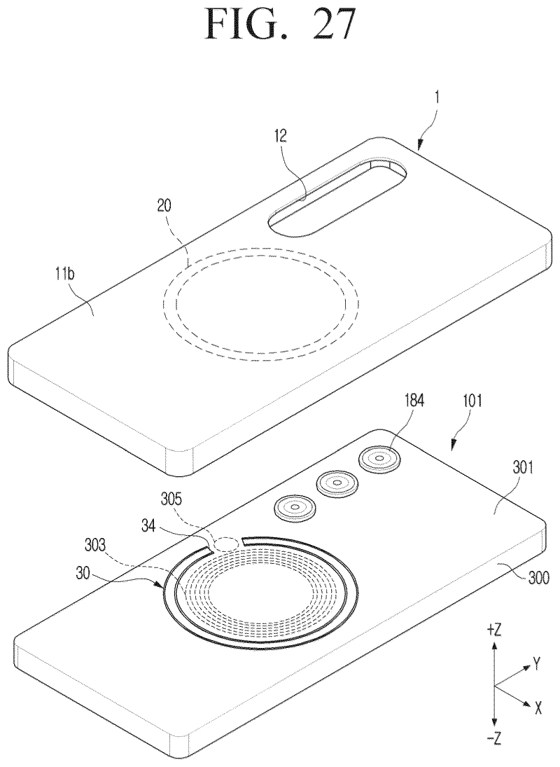

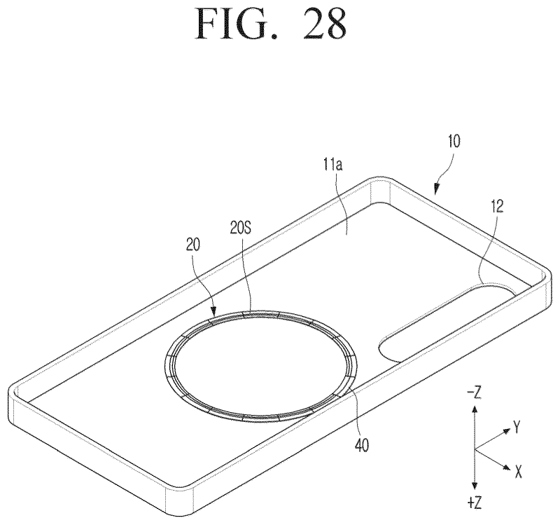

FIG. 26 is a perspective view illustrating an accessory cover coupled to an electronic device according to one or more embodiments of the disclosure. FIG. 27 is a perspective view illustrating a state in which an accessory cover is separated from an electronic device according to one or more embodiments of the disclosure. FIG. 28 is a bottom perspective view illustrating an accessory cover according to one or more embodiments of the disclosure.

Referring to FIGS. 26, 27, and 28, a device 1 according to one or more embodiments of the disclosure may include a case 10 and a magnetic structure 20.

The case 10 may be configured to be detachably coupled to an electronic device 101. The case 10 may be configured to accommodate the electronic device 101 in a shape corresponding to the electronic device 101. When the case 10 is coupled to the electronic device 101, the camera module 184 of the electronic device 101 may be positioned in the camera opening 12 of the case 10. The case 10 is identical to the case 10 of FIGS. 2 and 3 described above, and thus, a duplicated description thereof is omitted.

The magnetic structure 20 may be configured to be received in the magnetic shielding member 30 of the electronic device 101 when the case 10 is coupled to the electronic device 101. For example, the magnetic structure 20 may be formed in a circular loop corresponding to the magnetic shielding member 30 of the electronic device 101.

For example, the magnetic structure 20 may be disposed on the first surface 11a of the case 10. The lower surface (e.g., in the +Z direction) of the magnetic structure 20 may be attached to the first surface 11a of the case 10 using an adhesive.

According to an embodiment, the magnetic structure 20 may include a plurality of magnetic segments 20S. The plurality of magnetic segments 20S may be formed in an arc shape. The plurality of magnetic segments 20S may be arranged in a circular loop shape.

The plurality of magnetic segments 20S may be configured to provide an attractive force to be coupled to the external magnetic structure 203 of the external electronic device 200. The plurality of magnetic segments 20S may be configured in the same manner as the plurality of magnetic segments 20S of the device 1 according to the above-described embodiment, and thus, a duplicated description thereof is omitted.

The magnetic structure 20 may include a sensing magnet 40. The sensing magnet 40 may be formed in a shape similar to the magnetic segments 20S. The sensing magnet 40 may be identical to the sensing magnet 40 of the device 1 according to the above-described embodiment, and thus, a duplicated description thereof is omitted.

The magnetic shielding member 30 configured to shield a portion of the magnetic field of the magnetic structure 20 may be disposed on the electronic device 101.

The electronic device 101 may be coupled to the case 10 of the device 1 according to one or more embodiments of the disclosure. According to an embodiment, the electronic device 101 may be configured as a smartphone. For example, the electronic device 101 may include a housing 300, a rear cover 301, a camera module 184, a planar induction coil 303, a Hall sensor 305, and a magnetic shielding member 30.

For example, the housing 71 may be configured to support a display module 140. The display module 140 may be disposed on the front side (e.g., in the −Z direction) of the housing 300. The housing 300 may include a battery 171, a printed circuit board, and a charging device inside the housing 300.

The rear cover 301 may be configured to cover the rear side (e.g., in the +Z direction) of the housing 300. At least a portion of the camera module 184 may be exposed through one area of the rear cover 301.

The planar induction coil 303 may be disposed between the rear cover 301 and the battery 171. The planar induction coil 303 may be configured to function as a wireless charging antenna and/or an MST antenna.

The Hall sensor 305 may be configured to recognize the sensing magnet 40 of the device 1 according to one or more embodiments of the disclosure. The Hall sensor 305 may be disposed under the rear cover 301 (e.g., in the −Z direction). The Hall sensor 305 may be disposed to be adjacent to the sensing magnet 40 of the magnetic structure 20 when the electronic device 101 is coupled to the device 1 according to one or more embodiments of the disclosure.

As illustrated in FIG. 26, when the case 10 is coupled to the electronic device 101, the rear cover 301 of the electronic device 101 may be in contact with or adjacent to the first surface 11a of the case 10. At least a portion of the camera module 184 provided on the rear cover 301 of the electronic device 101 may be exposed to the outside through the camera opening 12 of the case 10. The planar induction coil 303 of the electronic device 101 may be located under a portion of the rear cover 301 corresponding to the inside of the magnetic shielding member 30 disposed on the rear cover 301, i.e., the inner circle formed by the inner circumferential surface of the magnetic shielding member 30. The Hall sensor 305 of the electronic device 101 may be located below a portion of the rear cover 301 corresponding to the sensing magnet 40 so as to be adjacent to the sensing magnet 40 of the magnetic structure 20 of the case 10.

The magnetic shielding member 30 may be configured to shield at least a portion of the magnetic force of the magnetic structure 20 in at least one direction.

The magnetic shielding member 30 may be disposed on the rear cover 301 of the electronic device 101. The magnetic shielding member 30 may be formed such that, when the case 10 is coupled to the electronic device 101, the magnetic shielding member 30 covers at least a portion of the magnetic structure 20. When the case 10 is coupled to the electronic device 101, a first portion 31 of the magnetic shielding member 30 may overlap at least a portion of one surface of the magnetic structure 20 when viewed in the +Z direction. The magnetic shielding member 30 may be attached to the rear cover 301 of the electronic device 101 using an adhesive.

The magnetic shielding member 30 may be configured in the same manner as the magnetic shielding member 30 of the device 1 according to the above-described embodiment, and thus, a duplicated description thereof is omitted.

The magnetic shielding member 30 may be disposed to reduce the influence of the magnetic field from the magnetic structure 20 located in the case 10 on various elements (e.g., a camera, a touchscreen) of the electronic device 101. These elements may include a structure capable of detecting input from an electronic pen (e.g., a stylus pen) using electromagnetic resonance (EMR) or active electrostatic solution (AES) technology embedded in the display module.

As illustrated in FIGS. 29, 30, and 31, at least one of the magnetic structure 20 and the magnetic shielding member 30 may be disposed within the case 10 of the device 1, i.e., between the first surface 11a and the second surface 11b.

FIG. 29 is a cross-sectional view illustrating a device to which an electronic device is coupled according to one or more embodiments of the disclosure.

Referring to FIG. 29, the magnetic structure 20 and the magnetic shielding member 30 may be disposed within the case 10 of the device 1, i.e., between the first surface 11a and the second surface 11b. The first portion 31 of the magnetic shielding member 30 may be disposed adjacent to the first surface 11a of the case 10, and the magnetic structure 20 may be disposed adjacent to the second surface 11b of the case 10.

The magnetic structure 20 and the magnetic shielding member 30 may be configured in the same manner as the magnetic structure 20 and the magnetic shielding member 30 of the device 1 according to the above-described embodiment, and thus, duplicated descriptions thereof are omitted.

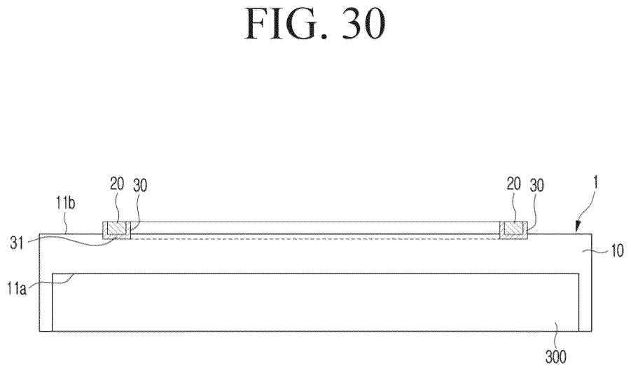

FIG. 30 is a cross-sectional view illustrating a device to which an electronic device is coupled according to one or more embodiments of the disclosure.

Referring to FIG. 30, the magnetic structure 20 may be disposed on the second surface 11b of the case 10, and a portion of the magnetic shielding member 30 may be disposed within the case 10 of the device 1, i.e., between the first surface 11a and the second surface 11b. The first portion 31 of the magnetic shielding member 30 may be disposed between the first surface 11a and the second surface 11b of the case 10, and at least a portion of the second portion 32 and the third portion 33 of the magnetic shielding member 30 may be exposed to the outside of the case 10 when viewed from the upper side of the second surface 11b of the case 10. The magnetic structure 20 may be disposed between the second portion 32 and the third portion 33 of the magnetic shielding member 30 protruding from the second surface 11b of the case 10.

The magnetic structure 20 and the magnetic shielding member 30 may be configured in the same manner as the magnetic structure 20 and the magnetic shielding member 30 of the device 1 according to the above-described embodiment, and thus, duplicated descriptions thereof are omitted.

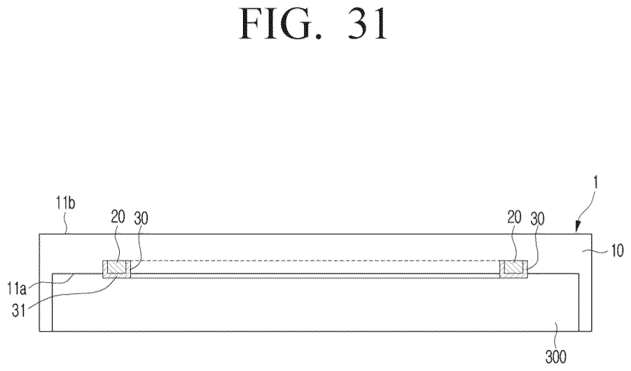

FIG. 31 is a cross-sectional view illustrating a device to which an electronic device is coupled according to one or more embodiments of the disclosure.

Referring to FIG. 31, portions of the magnetic structure 20 and the magnetic shielding member 30 may be disposed within the case 10, i.e., between the first surface 11a and the second surface 11b, and another portion of the magnetic shielding member 30 may be disposed so that at least a portion thereof is exposed to the outside of the case 10 when viewed from the first surface 11a of the case 10 of the device 1. The first portion 31 of the magnetic shielding member 30 may be disposed on the first surface 11a of the case 10, and the second portion 32 and the third portion 33 of the magnetic shielding member 30 may be disposed between the first surface 11a and the second surface 11b of the case 10. The magnetic structure 20 may be disposed between the second portion 32 and the third portion 33 of the magnetic shielding member 30 protruding inward from the first surface 11a of the case 10.

The magnetic structure 20 and the magnetic shielding member 30 may be configured in the same manner as the magnetic structure 20 and the magnetic shielding member 30 of the device 1 according to the above-described embodiment, and thus, duplicated descriptions thereof are omitted.

The magnetic structure 20 may further include an alignment magnet positioned around the magnetic structure 20. The alignment magnet may be provided for assisting the coupling of a device according to one or more embodiments of the disclosure with an external electronic device in a designated orientation. The alignment magnet may be configured in a structure in which an N pole magnet and an S pole magnet face each other with a non-magnetic area between them. The alignment magnet may be formed in a rectangular shape in the length direction of the electronic device. As an example, the alignment magnet may be connected to a magnet ring or may be formed to extend from the magnet ring.

A device 1 according to one or more embodiments of the disclosure may include a case 10 including a first surface 11a configured to be mechanically coupled to an electronic device 101 and a second surface 11b opposite to the first surface 11a. A first region of the case 10 may include an opening formed to expose at least a portion of a camera module provided in the electronic device 101 to the outside when coupled with the electronic device 101. The case 10 of the device may include a magnetic structure 20 disposed in a second region and having a loop shape to surround an outer periphery of a planar induction coil provided in the electronic device 101, and a magnetic shielding member 30 having a shape corresponding to the loop shape. The magnetic shielding member 30 may include a first portion 31 covering the upper surface of the magnetic structure 20, and a second portion 32 covering the outer side surface of the magnetic structure 20 at least disposed in a direction facing the opening 12.

Hereinafter, with reference to FIG. 32, a system for wirelessly charging a battery 171 of an electronic device 101 including a device 1 according to one or more embodiments of the disclosure will be described.

FIG. 32 is a view illustrating a wireless charging system for charging an electronic device coupled with a device according to one or more embodiments of the disclosure.

Referring to FIG. 32, a wireless charging system according to one or more embodiments of the disclosure may include an electronic device 101 and a charging station 200.

The electronic device 101 and the charging station 200 may be coupled and aligned with each other within a certain distance to wirelessly transmit/receive power. For example, power may be transmitted/received through magnetic coupling between induction coils disposed in the electronic device 101 and the charging station 200. For example, a magnetic field may be generated in an induction coil 201 formed of at least one wire concentrically wound on a plane, thereby charging the battery 171 provided in the electronic device 101. According to an embodiment, a magnetic resonance method may be used in addition to the magnetic induction method. Antennas (e.g., induction coils) for transmitting/receiving power between the electronic device 101 and the charging station 200 may be aligned with each other using a magnetic or mechanical fastening structure.

The electronic device 101 may include a smartphone or tablet. The electronic device 101 may be referred to as a portable electronic device or a user device. The electronic device 101 may include the battery 171 and the planar induction coil 303.

The charging station 200 may be configured to wirelessly charge the battery 171 of the electronic device 101. The charging station 200 may be referred to as a counterpart device or an external electronic device. The charging station 200 may be wired to a commercial power source 210 (e.g., an electrical outlet) to supply power for charging the electronic device 101. Alternatively, the charging station 200 may be wirelessly or wiredly connected to another external electronic device 102 (e.g., a personal computer PC, a laptop, a mass storage device).

The charging station 200 may receive power for charging from another external electronic device 102 wirelessly or wiredly. The charging station 200 may receive power for charging from a commercial power source 210, and may transmit/receive data by being connected to the memory of another external electronic device 102. Separate antennas for data communication may be disposed close to the induction coils in the electronic device 101 and the charging station 200. The charging station 200 may communicate data without another device through the memory and processor included in the charging station 200. The charging station 200 and another external electronic device 102 (e.g., a PC) described above may be a single device.

The electronic device 101 and the charging station 200 may each include a magnetic structure 20 and 203 (magnet structure, magnetic array, or magnetic ring) formed to provide a certain attractive force.

The magnetic structure 20 of the electronic device 101 may be formed in a loop shape that surrounds the outer periphery of the induction coil 303 of the electronic device 101. The magnetic structure 203 of the charging station 200 may be formed in a loop shape that surrounds the outer periphery of the induction coil 201 of the charging station 200. When the magnetic structure 20 of the electronic device 101 is magnetically coupled and aligned with the magnetic structure 203 of the charging station 200, the induction coil 303 of the electronic device 101 and the induction coil 201 of the charging station 200 may be aligned with each other.

The electronic device 101 may include a magnetic shielding member 30 disposed to cover at least a portion of the magnetic structure 20. According to an embodiment, the magnetic structure 20 and the magnetic shielding member 30 may be disposed in an accessory cover 1 that is detachably coupled to the electronic device 101.

Accordingly, when the electronic device 101 coupled with the accessory cover, i.e., the device 1 according to one or more embodiments of the disclosure is placed on the upper surface of the charging station 200, the magnetic structure 20 of the accessory cover 1 and the magnetic structure 203 of the charging station 200 may be magnetically coupled with each other. The battery 171 of the electronic device 101 may be wirelessly charged by the induction coil 303 of the electronic device 101 and the induction coil 201 of the charging station 200.

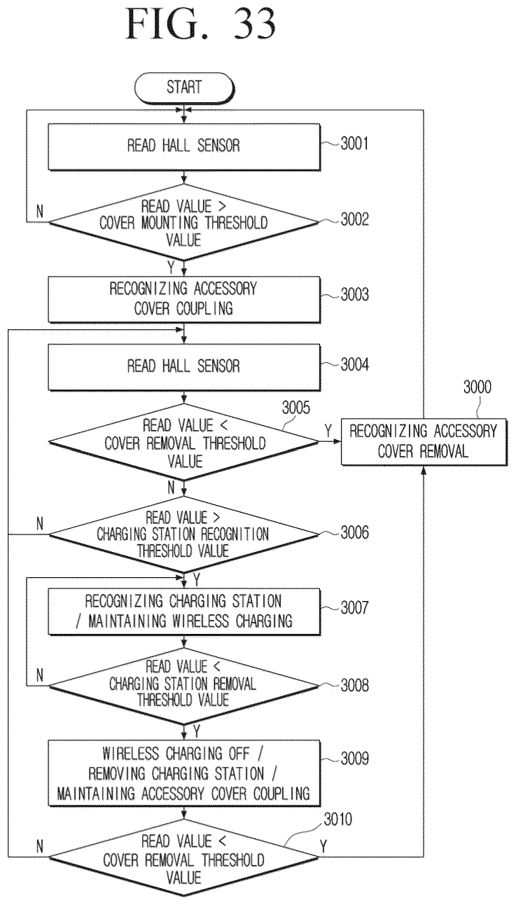

Hereinafter, a method for the processor 130 (see FIG. 1) of the electronic device 101 according to one or more embodiments of the disclosure to recognize the accessory cover 1 equipped with the magnetic structure 20 and control the electronic device 101 will be described in detail with reference to FIGS. 33, 34, and 35.

FIG. 33 is a flowchart illustrating a method for an electronic device to recognize an accessory cover and a charging station according to one or more embodiments of the disclosure. In FIG. 33, the operations may be performed sequentially, but are not necessarily performed sequentially. For example, the order of the operations may be changed, and at least two operations may be performed in parallel.

In operation 3001, the processor 130 of the electronic device 101 may read the Hall sensor 305. For example, the processor 130 may recognize a read value of the Hall sensor 305 through an electrical signal transmitted from the Hall sensor 305. Herr, the read value of the Hall sensor 305 may be the magnitude of the magnetic force detected by the Hall sensor 305.

In operation 3002, the processor 130 may identify whether the read value of the Hall sensor 305 is greater than a cover mounting threshold value. Here, the cover mounting threshold value may be the magnitude of an electrical signal output by the Hall sensor 305 when the Hall sensor 305 detects the sensing magnet 40 disposed on the accessory cover 1.

When the read value of the Hall sensor 305 is less than the cover mounting threshold value (operation 3002—N), the processor 130 may read the Hall sensor 305 in operation 3001.

When the read value of the Hall sensor 305 is greater than the cover mounting threshold value (operation 3002—Y), in operation 3003, the processor 130 may identify that the accessory cover 1 is mounted on the electronic device 101.

In operation 3004, the processor 130 may read the Hall sensor 305.

In operation 3005, the processor 130 may identify whether the read value of the Hall sensor 305 is smaller than a cover removal threshold value. Here, the cover removal threshold value may be the magnitude of an electrical signal output by the Hall sensor 305 when the accessory cover 1 is removed from the electronic device 101.

When the read value of the Hall sensor 305 is smaller than the cover removal threshold value (operation 3005—Y), in operation 3000, the processor 130 may recognize that the accessory cover 1 has been removed or detached from the electronic device 101.

When the read value of the Hall sensor 305 is greater than or equal to the cover removal threshold value (operation 3005—N), in operation 3006, the processor 130 may check whether the read value of the Hall sensor 305 is greater than a charging station recognition threshold value. Here, the charging station recognition threshold value may be the magnitude of an electrical signal output by the Hall sensor 305 when the Hall sensor 305 detects the magnetic structure 203 of the charging station 200. For example, the charging station recognition threshold value may be greater than the cover mounting threshold value.

When the read value of the Hall sensor 305 is less than or equal to the charging station recognition threshold value (operation 3006—N), in operation 3004, the processor 130 may read the Hall sensor 305 again.

When the read value of the Hall sensor 305 is greater than the charging station recognition threshold value (operation 3006—Y), in operation 3007, the processor 130 may recognize that the electronic device 101 coupled with the accessory cover 1 is positioned at the charging station 200 and maintain wireless charging. For example, the electronic device 101 may perform operations for performing wireless charging with the charging station 200.

In operation 3008, the processor 130 may identify whether the read value of the Hall sensor 305 is less than a charging station removal threshold value. When the read value of the Hall sensor 305 is greater than or equal to the charging station removal threshold value (operation 3008—N), in operation 3007, the processor 130 may recognize that the electronic device 101 coupled with the accessory cover 1 is positioned at the charging station 200 and maintain wireless charging.

When the read value of the Hall sensor 305 is less than the charging station removal threshold value (operation 3008—Y), in operation 3009, the processor 130 may turn off wireless charging. In addition, in operation 3009, the processor 130 may recognize that charging station 200 has been removed and maintain the recognition that the accessory cover 1 is coupled.

In operation 3010, the processor 130 may read the Hall sensor 305 and identify whether the read value of the Hall sensor 305 is less than the cover removal threshold value.

When the read value of the Hall sensor 305 is less than the cover removal threshold value (operation 3010—Y), in operation 3000, the processor 130 may recognize that the accessory cover 1 has been removed or detached from the electronic device 101. The processor 130 may read the Hall sensor 305 again in operation 3001.

When the read value of the Hall sensor 305 is equal to or greater than the cover removal threshold value (operation 3010—N), in operation 3004, the processor 130 may read the Hall sensor 305 again.

The electronic device 101 according to one or more embodiments of the disclosure may include the Hall sensor 305 configured to recognize the magnetic structure 20 of the accessory cover 1, a memory 120 configured to store instructions, and at least one processor 130.

When the at least one processor 130 recognizes that the accessory cover 1 is coupled through the Hall sensor 305 while executing instructions individually or collectively, the processor 130 may control at least one of the camera module 184 and the display module differently from when the accessory cover 1 is not coupled.

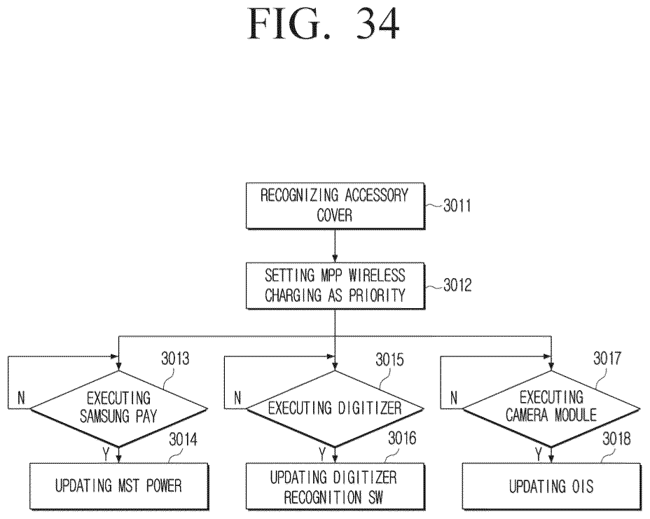

Hereinafter, with reference to FIG. 34, a method for optimizing the performance of an electronic device 101 when a processor 130 of the electronic device 101 recognizes an accessory cover 1 according to one or more embodiments of the disclosure will be described.

FIG. 34 is a flowchart illustrating a method for optimizing performance when an electronic device recognizes an accessory cover according to one or more embodiments of the disclosure. In FIG. 34, the operations may be performed sequentially, but are not necessarily performed sequentially. For example, the order of the operations may be changed, and at least two operations may be performed in parallel.

Referring to FIG. 34, in operation 3011, the processor 130 may recognize the accessory cover 1. In operation 3012, when recognizing the accessory cover 1, the processor 130 may set MPP wireless charging as a priority. For example, after recognizing the accessory cover 1, the processor 130 may set MPP as a priority among basic power protocol (BPP), extended power protocol (EPP), and/or magnetic power protocol (MPP), which are wireless charging protocols supported by the electronic device 101.

In one embodiment, in operation 3013, the processor 130 may identify whether Samsung Pay is executed while the accessory cover 1 is coupled to the electronic device 101. When Samsung Pay is executed in the electronic device 101 coupled with the accessory cover 1 (operation 3013—Y), i.e., when the magnetic secure transmission (MST) antenna is in operation, the processor 130 may update the MST power in operation 3014. Alternatively, the processor 130 may update the MST power at the time when the accessory cover 1 is coupled to the electronic device 101. As an example, when the MST antenna is operating, the processor 130 may set the peak current regulation (PCR) current value of the MST power to a high value. The PCR current value may be set to the maximum value in consideration of the recognition compatibility of a point of sale (POS) device that recognizes Samsung Pay. In addition, the processor 130 may adjust the voltage value of the MST power.

In one embodiment, in operation 3015, the processor 130 may identify whether a digitizer is running while the accessory cover 1 is coupled to the electronic device 101. The digitizer may be an example of a stylus pen that can input commands to the electronic device 101 by touching or hovering the screen. When the digitizer is running in the electronic device 101 coupled with the accessory cover 1 (operation 3015—Y), in operation 3016, the processor 130 may update a digitizer recognition software (SW) to increase the recognition rate of the digitizer. Alternatively, the processor 130 may update the digitizer recognition software at the time when the accessory cover 1 is coupled to the electronic device 101. For example, when the accessory cover 1 is coupled to the electronic device 101, the magnetic permeability of the ferrite core inside the digitizer may be lowered by the magnetic structure 20 of the accessory cover 1. When the magnetic permeability of the ferrite core of the digitizer is lowered, the inductor value of the ferrite coil may be changed. When the inductor value of the ferrite coil is changed, the LC resonance frequency may be changed, and the processor 130 may not recognize the digitizer. When the accessory cover 1 is coupled to the electronic device 101, the processor 130 may update the digitizer recognition software to adjust the LC resonance frequency so as to be able to recognize the digitizer.

In one embodiment, in operation 3017, the processor 130 may identify whether the camera module 184 is running while the accessory cover 1 is coupled to the electronic device 101. When the camera module 184 is running while the accessory cover 1 is coupled to the electronic device 101 (operation 3017—Y), in operation 3018, the processor 130 may update the optical image stabilization (OIS) of the camera module 184 so that the OIS operates properly. Alternatively, the processor 130 may update the OIS at the time when the accessory cover 1 is coupled to the electronic device 101. When the accessory cover 1 is coupled to the electronic device 101, the OIS may be affected by the magnetic structure 20 of the accessory cover 1. As an example, when the accessory cover 1 is coupled to the electronic device 101, vibration may be generated by the magnetic structure 20. Then, a gyroscope sensor may detect the amount of vibration and transmit it to an OIS micro control unit (MCU). The OIS MCU may transmit a target signal to a driver integrated circuit (IC) to move a lens or sensor in a direction opposite to the vibration. The driver IC may transmit a signal to a driver of the camera module 184 based on the target signal to move the lens or image sensor, thereby correcting the OIS.

In one embodiment, in operation 3011, when the processor 130 recognizes the accessory cover 1, the processor 130 may output a user interface indicating that some errors may occur in functions related to MST, NFC, stylus pen, camera, and/or antenna.

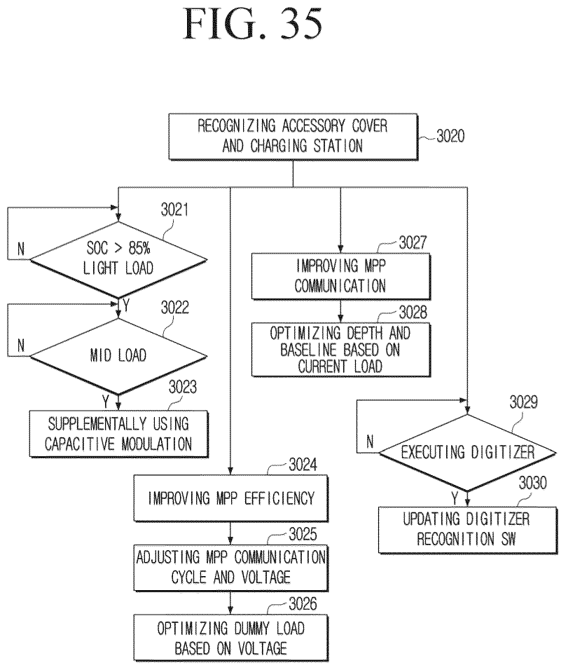

Hereinafter, with reference to FIG. 35, a method for optimizing the performance of an electronic device 101 when a processor 130 of the electronic device 101 recognizes an accessory cover 1 and a charging station 200 according to one or more embodiments of the disclosure will be described.

FIG. 35 is a flowchart illustrating a method for optimizing performance when an electronic device recognizes an accessory cover and a charging station according to one or more embodiments of the disclosure. In FIG. 35, the operations may be performed sequentially, but are not necessarily performed sequentially. For example, the order of the operations may be changed, and at least two operations may be performed in parallel.

In operation 3020, when the processor 130 of the electronic device 101 according to one or more embodiments of the disclosure recognizes the accessory cover 1 and the charging station 200, the processor 130 may perform wireless charging.

In operation 3021, the processor 130 may identify whether the state of charge (SOC) of the battery 171 exceeds 85% and the current is a light load during wireless charging. When the SOC of the battery 171 exceeds 85% and the current is the light load (operation 3021—Y), in operation 3022, the processor 130 may identify whether the current is a heavy load. When the current is a heavy load (operation 3022—Y), in operation 3023, the processor 130 may supplementally use capacitive modulation. Using capacitive modulation may improve the stability of communication.

In one embodiment, in operation 3020, when the processor 130 recognizes the accessory cover 1 and the charging station 200, in operation 3024, the processor 130 may perform an operation to improve MPP efficiency while simultaneously performing wireless charging. In one embodiment, when the temperature of the electronic device 101 reaches a threshold value during wireless charging at the default value, the processor 130 may perform an operation to improve MPP efficiency. In operation 3025, the processor 130 may adjust the MPP communication cycle and voltage. In operation 3026, the processor 130 may optimize a dummy load based on the voltage.

In one embodiment, in operation 3020, when the processor 130 recognizes the accessory cover 1 and the charging station 200, in operation 3027, the processor 130 may perform an operation to simultaneously improve MPP communication while performing wireless charging. In one embodiment, when an MPP communication error occurs three or more times, the processor 130 may perform an operation to improve the MPP communication. In operation 3028, the processor 130 may optimize the depth and baseline based on the current load.

An example of current, depth, and baseline depending on the current load is disclosed in Table 1.

TABLE 1

| load | light load | mid load | heavy load |
|---|---|---|---|
| current | 600 mA or less | 600 mA or more | 1.25 A or more |
| depth | 50 | 50 | 70 |
| baseline | 70 | 0 | 0 |

For example, under light load, the processor 130 may increase the baseline to 70 mA through a dummy load. Under heavy load, the processor 130 may increase the depth value to 70 to improve the quality of amplitude shift keying (ASK) communication.

In one embodiment, in operation 3029, the processor 130 may identify whether the digitizer is running during wireless charging. When the digitizer is running during wireless charging (operation 3029—Y), in operation 3030, the processor 130 may update the digitizer recognition software to increase the recognition rate of the digitizer. During wireless charging of the electronic device 101, the processor 130 may adjust the LC resonance frequency by updating the digitizer recognition software to recognize the digitizer.

A device 1 according to one or more embodiments of the disclosure described above may include at least one connector (or contact) that can be electrically connected to an electronic device 101. Power may be transmitted through the at least one connector. Information related to the device 1 (e.g., an identifier, a manufacturer, and included components of the device 1) may be transmitted to the electronic device 101 through the at least one connector. The device 1 may include a separate antenna and/or IC for near-field communication (e.g., NFC).

One or more embodiments of the disclosure described above may be applied to an accessory cover for a rollable, foldable, or multi-foldable electronic device.

A foldable electronic device may include a flexible display including housing portions (e.g., first and second housings) that are rotatably connected to each other about a folding axis, and display portions (e.g., first and second display areas) accommodated in the housing portions. A hinge assembly coupled to each housing and supporting a folding function may be disposed between the first and second housings. A hinge housing configured to accommodate at least a portion of the hinge assembly may be disposed between the first and second housings.

The folding axis of the foldable electronic device may support either an in-folding or an out-folding method. The in-folding may correspond to a method in which corresponding display areas are folded in a direction facing each other. An in-folding hinge portion may include a hinge housing. The out-folding may correspond to a method in which corresponding display areas are folded in a direction that does not face each other. An out-folding hinge portion may not include a hinge housing.

The multi-foldable electronic device may include a first housing, a second housing rotatably connected to the first housing about a first folding axis, and a third housing rotatably connected to the second housing about a second folding axis. The multiple electronic device may include a flexible display including first, second, and third display areas accommodated in the first, second, and third housings. The multi-foldable electronic device may include three or more folding axes and four or more housing portions.

The first folding axis of the multi-foldable electronic device may support out-folding, and the second folding axis may support in-folding. For example, the first and second housings may be folded in an out-folding manner, and the second and third housings may be folded in an in-folding manner. The magnetic shielding member 30 of the device 1 according to one or more embodiments of the disclosure described above may be disposed on a rear cover portion (e.g., between the battery 171 and the rear cover) of a housing (e.g., the third housing) that folds in the in-folding manner with respect to another housing. In the case of the multi-foldable electronic device, the magnetic shielding member 30 of the device 1 according to one or more embodiments of the disclosure described above may be disposed on a plurality of cover portions that are coupled to a plurality of housing portions. The housing portions may refer to separate, detachable housings or respective areas of one housing.

One or more embodiments of the disclosure may be implemented in electronic devices, including wearable devices (e.g., smart watches, augmented reality (AR), virtual reality (VR), glasses type, or smart rings), and covers for the electronic devices (e.g., cases for charging and storing earbuds, or keyboard cases for tablets).

The counterpart device that transmits and receives power and/or data to/from the user device of the disclosure may be a smartphone, a smart watch, a charging station 200, a docking station, or a portion of an electronic device disposed in a vehicle. At least one of the two devices may include a structure capable of changing the direction of magnetic force, the arrangement of the magnets, and/or the arrangement of the housing containing the magnets, depending on conditions. The two devices may further include mechanical coupling structures.

At least a portion of the structure of the disclosure (the induction coil 303, the magnetic structure 20, and the magnetic shielding member 30) may be formed in a shape corresponding to the shape of the housing where it is disposed. At least a portion of the induction coil 303, the magnetic structure 20, or the magnetic shielding member 30 may have a curved shape depending on the shape of the corresponding housing. The structure of the disclosure may be disposed on the upper/lower/left/right sides of the electronic device 101 in addition to the rear cover. The magnetic structure 20 and the magnetic shielding member 30 may be formed in various shapes in addition to the loop shape.

In the foregoing, the disclosure has been shown and described with reference to various embodiments. However, it is understood by those skilled in the art that various changes may be made in form and detail without departing from the scope of the disclosure as defined by the appended claims and equivalents thereof.

What is claimed is:

1. A device comprising:
a case configured to be detachably coupled to an electronic device comprising a camera and a planar induction coil, the case comprising:
a first surface in contact with the electronic device in a state in which the case is coupled to the electronic device;
a second surface opposite to the first surface; and
a camera opening exposing at least a portion of the camera to an outside in the state in which the case is coupled to the electronic device;
a magnetic structure disposed in or on the case and having a loop shape surrounding the planar induction coil of the electronic device in the state in which the case is coupled to the electronic device; and
a magnetic shielding member having a shape corresponding to the loop shape of the magnetic structure,
wherein the magnetic shielding member comprises:
a first portion interposed between the electronic device and the magnetic structure in the state in which the case is coupled to the electronic device and configured to cover a lower surface of the magnetic structure; and
a second portion facing the camera opening and configured to cover an outer side surface of the magnetic structure.

2. The device of claim 1, wherein the second portion of the magnetic shielding member extends from an outer end of the first portion and is bent to cover the outer side surface of the magnetic structure, and
wherein the second portion of the magnetic shielding member is configured to shield at least a portion of a magnetic field generated by the magnetic structure in a direction of the camera opening.

3. The device of claim 2, wherein the magnetic shielding member further comprises a third portion extending from an inner end of the first portion and bent to cover an inner side surface of the magnetic structure, and
wherein the third portion is configured to shield at least a portion of the magnetic field generated by the magnetic structure in a direction of the planar induction coil of the electronic device.

4. The device of claim 3, wherein a first height of the second portion of the magnetic shielding member is equal to a second height of the third portion of the magnetic shielding member.

5. The device of claim 3, wherein the second portion of the magnetic shielding member completely covers the outer side surface of the magnetic structure, and
wherein the third portion of the magnetic shielding member completely covers the inner side surface of the magnetic structure.

6. The device of claim 1, wherein the magnetic shielding member comprises:
a first section comprising the first portion and the second portion; and
a second section comprising the first portion without the second portion, and
wherein the first section is closer to the camera opening than the second section.

7. The device of claim 6, wherein the second section of the magnetic shielding member comprises an opening from which a portion of the first portion of the magnetic structure is removed.

8. The device of claim 1, wherein the case further comprises another magnetic shielding member separated from the magnetic shielding member and disposed around the camera opening.

9. The device of claim 6, wherein the magnetic structure comprises a plurality of magnetic segments having an arc shape, and
wherein the first section has a length corresponding to at least one magnetic segment among the plurality of magnetic segments.

10. The device of claim 9, wherein the magnetic structure is configured to couple the second surface of the case to an external electronic device comprising an external magnetic structure through attractive force between the magnetic structure and the external magnetic structure, and
wherein the plurality of magnetic segments of the magnetic structure comprise a first magnetic segment group having a first magnetic pole arrangement configured to provide the attractive force to be coupled to the external magnetic structure of the external electronic device.

11. The device of claim 10, wherein the plurality of magnetic segments further comprise a second magnetic segment group that is closer to the camera opening than the first magnetic segment group and has a second magnetic pole arrangement different from the first magnetic pole arrangement.

12. The device of claim 11, wherein the electronic device comprises a Hall sensor, and
wherein the plurality of magnetic segments further comprise a third magnetic segment having a third magnetic pole arrangement detected by the Hall sensor of the electronic device.

13. The device of claim 1, wherein the first portion of the magnetic shielding member is attached to the second surface of the case, and the magnetic shielding member is interposed between the case and the magnetic structure.

14. The device of claim 1, wherein the magnetic structure is attached to the first surface of the case, and
the magnetic shielding member covers the magnetic structure.

15. An electronic device comprising:
a camera;
a display;
a battery overlapping at least a portion of the display;
a cover comprising an opening through which at least a portion of the camera is exposed, the cover being configured to be coupled to an external case comprising a magnetic structure;
a planar induction coil between the battery and an outer surface of the cover, the planar induction coil being configured to receive power for charging the battery; and
a magnetic shielding member in or on the cover, surrounding at least a portion of an outer periphery of the planar induction coil, and having a loop shape,
wherein the magnetic shielding member comprises:
a first portion between the cover and the magnetic structure and covering at least a portion of a surface of the magnetic structure based on the cover being coupled to the external case; and
a second portion extending from an outer end of the first portion, bent in a direction opposite to the cover, and facing the camera.

16. The electronic device of claim 15, wherein the magnetic shielding member comprises:
a first section comprising the first portion and the second portion; and
a second section comprising the first portion without the second portion, and
wherein the first section is closer to the opening of the cover than the second section.

17. The electronic device of claim 15, further comprising:
a Hall sensor configured to recognize the magnetic structure;
a memory storing instructions, and
at least one processor configured to execute the instructions individually or collectively to, based on recognizing that the external case is coupled to the cover through the Hall sensor, control at least one of the camera or the display differently from a state in which the external case is not coupled to the cover.

18. A device comprising:
a case configured to be detachably coupled with an electronic device comprising a camera and a planar induction coil, the case comprising:
a first surface in contact with the electronic device;
a second surface opposite to the first surface; and
a camera opening exposing at least a portion of the camera to an outside in a state in which the case is coupled to the electronic device;
a magnetic structure disposed in or on the case adjacent to the camera opening, having a loop shape, and surrounding the planar induction coil of the electronic device; and
a magnetic shielding member having a shape corresponding to the magnetic structure,
wherein the magnetic structure comprises an inner magnet and an outer magnet disposed concentrically around the inner magnet, and
wherein the inner magnet and the outer magnet are disposed in a Halbach arrangement.

19. The device of claim 18, wherein magnetic poles of the inner magnet are disposed vertically, magnetic poles of the outer magnet are disposed horizontally, and a ratio of a width of the inner magnet to a width of the outer magnet is 1:2.

20. The device of claim 18, wherein magnetic poles of the inner magnet are disposed horizontally, magnetic poles of the outer magnet are disposed vertically, and a ratio of a width of the inner magnet to a width of the outer magnet is 2:1.
